(19) United States
(12) Patent Application Publication
(10) Pub. No.: US 2026/0161094 A1
(43) Pub. Date: Jun. 11, 2026

(54) HIGH FIDELITY 3D PRINTING THROUGH COMPUTED AXIAL LITHOGRAPHY

(71) Applicant: The Regents of the University of California, Oakland, CA (US)

(72) Inventors: Joseph TOOMBS, Oakland, CA (US); Chi Chung LI, Oakland, CA (US); Hayden TAYLOR, Oakland, CA (US); Indrasen BHATTACHARYA, Oakland, CA (US); Jingzhao ZHANG, Oakland, CA (US); Vishal BANSAL, Oakland, CA (US); Ingrid SHAN, Oakland, CA (US)

(73) Assignee: The Regents of the University of California, Oakland, CA (US)

(21) Appl. No.: 18/707,307

(22) PCT Filed: Nov. 4, 2022
(86) PCT No.: PCT/US2022/049028

§ 371 Date: May 3, 2024

Related U.S. Application Data
(60) Provisional application No. 63/276,380, filed on Nov. 5, 2021.

(51) Int. Cl. G03F 7/00; G01N 21/41

(52) U.S. Cl. CPC G03F 7/70091; G01N 21/41; G03F 7/70533; G03F 7/7085

(57) ABSTRACT

A system and method of producing a three-dimensional object are provided. The method includes providing a volume of radiation-reactive material; illuminating the radiation-reactive material with patterned radiation such that a portion of the volume of radiation-reactive material corresponding to the three-dimensional object reacts to form the three-dimensional object and a remaining portion remains unreacted; and removing the remaining portion of the radiation-reactive material to provide the three-dimensional object. The illuminating the radiation-reactive material with patterned radiation is based on a minimization of deviations of an energy deposition density below a first threshold in an object zone, an unconstrained buffer zone surrounding the object zone, and a minimization of deviations of energy deposition density above a second threshold in a zone surrounding the buffer zone. The object zone corresponds to a location of the three-dimensional object.

### CROSS REFERENCE TO RELATED APPLICATIONS

The present patent application claims priority benefit to U.S. Provisional Patent Application No. 63/276,380, filed on Nov. 5, 2021, the entire contents of which is incorporated herein by reference.

### STATEMENT REGARDING FEDERALLY SPONSORED RESEARCH OR DEVELOPMENT

This invention was made with government support under grant number 1160494 awarded by the National Science Foundation (NSF). The government has certain rights in the invention.

### BACKGROUND

### 1. Technical Field

The field of currently claimed embodiments relate to three-dimensional printing and more particularly to systems and methods for high fidelity three-dimensional printing through computed axial lithography.

### 2. Discussion of Related Art

A large majority of additive manufacturing (AM) modalities developed to date employ unit material deposition/solidification processes with lower dimensionality than the resultant 3D fabricated part, each typically constructing the part serially with 2D layers. Fused filamentfabrication, selective laser sintering and melting, and stereolithography (SLA) scan layers point-by-point, inkjet and binder jet printing scan layers line-by-line, and digital light processing (DLP) SLA and continuous liquid interface production print entire layers without scanning. Due to their serial nature, many of these methods require support structures, print times can reach many tens of minutes to hours, the staircasing effect of layers can lead to rough surfaces, and anisotropic part mechanical properties may emerge. Advances in 4+ axis motion planning aim to alleviate these problems but more complex machine paths often result in more expensive hardware and more computationally expensive path generation and control. Recent developments in volumetric additive manufacturing (VAM) have taken a different approach, to polymerize simultaneously all points in the part by controlling the 3D superposition of light exposure dose through orthogonal or tomographic techniques. VAM is layer-less and recent implementations have demonstrated support-free fabrication of cm-scale parts having low surface roughness and isotropic mechanical properties in seconds to minutes. Because all points in the part are cured simultaneously, this emerging technique is at the frontier of AM efficiency in terms of resolution and throughput when compared to the preceding layer-by-layer methods, and maturation of the hardware and computational methods supporting VAM will help to establish further and even expand its capabilities.

Tomographic VAM or Computed Axial Lithography (CAL) proposed by Kelly et al. derives many of its working principles from computed tomography (CT), an important non-invasive medical and nondestructive industrial 3D imaging modality. In conventional CT imaging X-rays are transmitted at a series of angles through a static subject, with the attenuation being recorded after transmission as a series of 2D projections in a 3D data set (radius, height, angle). The computational tomographic reconstruction of the subject's 3D attenuation map (X, Y, Z) is typically realized by the Fourier slice theorem and various other iterative or direct algorithms which have no particular physically established constraints on the projections.

The inverse problem of physical tomographic construction in the context of CAL is more challenging. In this case, physical time-multiplexed projections of visible or ultraviolet radiation are absorbed by a relevant chemical photo-initiator. The physical radiation source naturally leads to a positivity constraint on the projection space, and typically an upper bound as well due to limitations on the maximum intensity from the radiation source.

The goal of the optimization is to pre-calculate a spatial distribution of intensity such that after projection over angles, the accumulated energy dose is below a certain threshold in ‘background’ regions to prevent solidification and above a (higher) threshold in ‘target’ regions to solidify the resin and lead to selective photopolymerization. The target and background dose requirements are specified as inputs to the mathematical problem and the set of calculated intensities (of finite nonnegative range limited by DLP dynamic range) is the desired output. Previous approaches have used a heuristic finite difference gradient descent method based on anomalously printed regions or have used only filtering and no optimization to generate the projections. (See EXAMPLES below for reference citations.) There thus remains a need for improved methods and systems for high fidelity three-dimensional printing.

### SUMMARY OF THE DISCLOSURE

An aspect of the present disclosure is to provide a method of producing a three-dimensional object. The method includes providing a volume of radiation-reactive material; illuminating the radiation-reactive material with patterned radiation such that a portion of the volume of radiation-reactive material corresponding to the three-dimensional object reacts to form the three-dimensional object and a remaining portion remains unreacted; and removing the remaining portion of the radiation-reactive material to provide the three-dimensional object. The illuminating the radiation-reactive material with patterned radiation is based on a minimization of deviations of an energy deposition density below a first threshold in an object zone, an unconstrained buffer zone surrounding the object zone, and a minimization of deviations of energy deposition density above a second threshold in a zone surrounding the buffer zone. The object zone corresponds to a location of the three-dimensional object.

In an embodiment, a loss function is defined as a function of the deviations of the energy deposition density below the first threshold, and of the deviations of energy deposition density above the second threshold. The loss function is minimized to determine the illuminating to be performed.

In an embodiment, the loss function is a continuous differentiable function. In an embodiment, the loss function is:

$${ℒ}_{PM} [ t ] := {ρ}_{1} {\int }_{\sim {V}_{2} [ t ]} ( f ( r ) - {d}_{l} ) d r + {ρ}_{2} {\int }_{\sim {V}_{1} [ t ]} ( {d}_{h} - f ( r ) ) d r .$$

as further defined in the following paragraphs.

In an embodiment, wherein the radiation-reactive material is a photoactive material. The illuminating the radiation-reactive material with patterned radiation is an optical computed axial lithographic illuminating.

Another aspect of the present invention is to provide a system for producing a three-dimensional object. The system includes a target volume structured to contain radiation-reactive material; and an illumination system configured to be arranged proximate the target volume. The illumination system is configured to provide patterned radiation such that a portion of the volume of radiation-reactive material corresponding to the three-dimensional object reacts to form the three-dimensional object and a remaining portion remains unreacted. The illumination system is further configured to provide the patterned radiation based on a minimization of deviations of an energy deposition density below a first threshold in an object zone, an unconstrained buffer zone surrounding the object zone, and a minimization of deviations of energy deposition density above a second threshold in a zone surrounding the buffer zone. The object zone corresponds to a location of the three-dimensional object.

In an embodiment, a loss function is defined as a function of the deviations of the energy deposition density below the first threshold, and of the deviations of energy deposition density above the second threshold. The loss function is minimized to determine the illuminating to be performed.

In an embodiment, the loss function is a continuous differentiable function. In an embodiment, the loss function is:

$${ℒ}_{PM} [ t ] := {ρ}_{1} {\int }_{∼ {V}_{2} [ t ]} ( f ( r ) - {d}_{l} ) dr + {ρ}_{2} {\int }_{∼ {V}_{1} [ t ]} ( {d}_{h} - f ( r ) ) dr .$$

as further defined in the following paragraphs.

In an embodiment, the radiation-reactive material is a photoactive material. The illumination system is an optical computed axial lithographic illumination system.

Another aspect of the present invention is to provide a method of producing a three-dimensional object. The method includes providing a volume of photoreactive material; illuminating the photoreactive material with patterned light such that a portion of the volume of photoreactive material corresponding to the three-dimensional object reacts to form the three-dimensional object and a remaining portion remains unreacted; measuring changes in refractive index of the photoreactive material during the illuminating using color schlieren tomographic imaging; determining exposure errors in the volume of photoreactive material during the illuminating and modifying the illuminating to correct at least some of the exposure errors; and removing the remaining portion of the photoreactive material to provide the three-dimensional object.

Yet another embodiment of the present invention is to provide a system for producing a three-dimensional object. The system includes a target volume structured to contain photoactive material; an optical computed axial lithographic illumination system arranged proximate the target volume structured; and a color schlieren tomographic imaging system arranged proximate the target volume structured. The color schlieren tomographic imaging system is configured to communicate with the optical computed axial lithographic illumination system to provide feedback control thereof.

### BRIEF DESCRIPTION OF THE DRAWINGS

The present disclosure, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention.

FIG. 1 is a schematic diagram of a system for producing a three-dimensional (3D) object, according to an embodiment of the present invention;

FIG. 2A is a schematic diagram of a Computed Axial Lithography (CAL) system, according to an embodiment of the present invention;

FIG. 2B isa schematic representation of a 3D dose formation that occurs through the integral of projections across angles as the resin container rotates (example back-projections shown here for angles θᵢ, θⱼ, θₖ, θₗ), with higher accumulated dose where higher intensity projections locally overlap, according to an embodiment of the present invention;

FIG. 2C is a schematic representation of the target, buffer and background regions that are derived from the print geometry, according to an embodiment of the present invention;

FIG. 2D is a schematic representation of the target illumination at every iteration, violating regions are determined based on the dose distribution and constraint requirements, according to an embodiment of the present invention;

FIG. 2E is a schematic representation showing the loss gradient for the update determined based on violating regions, according to an embodiment of the present invention;

FIG. 2F are various optimization curves showing the loss versus optimization epochs, according to an embodiment of the present invention;

FIG. 3A shows a converged projection intensity (at three exemplary angles) for DM with unfiltered initialization, with resulting calculated 3D dose distribution shown on the right in the same row, according to an embodiment of the present invention;

FIG. 3B shows a converged projector intensity for PM with unfiltered initialization, with resulting 3D dose on the right, according to an embodiment of the present invention;

FIG. 3C shows a converged projection intensity same as FIG. 3A but with Shepp-Logan filtered (positivity-constrained) initialization, according to an embodiment of the present invention;

FIG. 3D shows a converged projection intensity same as FIG. 3B, but with filtered initialization as in FIG. 3C, according to an embodiment of the present invention;

FIG. 3E shows the target geometry at exemplary Z-slices, according to an embodiment of the present invention;

FIG. 4A shows a converged projection intensity (at three exemplary angles) for DM with unfiltered initialization, with resulting calculated 3D dose distribution shown on the right in the same row, according to an embodiment of the present invention;

FIG. 4B shows a converged projection intensity for PM and unfiltered initialization, with resulting 3D dose on the right, according to an embodiment of the present invention;

FIG. 4C shows a converged projection intensity same as FIG. 4A but with Shepp-Logan filtered (positivity-constrained) initialization, according to an embodiment of the present invention;

FIG. 4D shows a converged projection intensity same as FIG. 4B, but with filtered initialization as in FIG. 4C, according to an embodiment of the present invention;

FIG. 4E shows the target geometry at exemplary Z-slices, according to an embodiment of the present invention;

FIG. 5A is a plot of mIoU vs. dose threshold for projections generated via unfiltered initialization (for both DM and PM approaches), according to an embodiment of the present invention;

FIG. 5B is a plot of mIoU vs. dose threshold as in FIG. 5A, but for projections generated by Shepp-Logan (positivity constrained) filtered initialization, according to an embodiment of the present invention;

FIG. 5C show a simulated signed deviation histogram between target and best simulated geometries using PM optimization and filtered initialization, according to an embodiment of the present invention;

FIG. 5D shows a voxelated target geometry with signed deviation colormap where red indicates the simulated surface lies outside the target surface and blue indicates the simulated surface lies inside the target surface, according to an embodiment of the present invention;

FIG. 6A shows signed deviation histograms comparing the laser-scanned surface to its respective target surface (PM (red) and DM (blue)), according to an embodiment of the present invention;

FIG. 6B shows Laser scanned 3D surfaces with signed deviation colomap where red indicates the laser-scanned surface lies outside the target surface and blue indicates the laser-scanned surface lies inside the target surface, according to an embodiment of the present invention;

FIG. 6C are photographs of printed and scanned geometries, according to an embodiment of the present invention;

FIG. 7 shows the absorption spectrum of the resin formulation in units of inverse length (left axis) and the normalized light intensity spectrum of the projector (right axis), according to an embodiment of the present invention;

FIG. 8 shows a VAM metrology methodology using CloudCompare point cloud software, according to an embodiment of the present invention;

FIG. 9A shows a signed deviation histograms (red) comparing laser scan surface to target geometry, normalized to a percentage of the maximum bounding box dimension of the underlying target geometry, according to an embodiment of the present invention;

FIG. 9B shows a Laser-scanned 3D surface with signed deviation colormap where red indicates laser-scanned surface lies outside the target surface and blue indicates the laser-scanned surface lies inside the target surface, according to an embodiment of the present invention;

FIG. 9C shows photographs of printed and scanned geometries, according to an embodiment of the present invention;

FIG. 10A shows a signed deviation histograms (blue) comparing laser scan surface to the PM best simulated surface geometry, normalized to a percentage of the maximum bounding box dimension of the underlying target geometry, according to an embodiment of the present invention;

FIG. 10B shows a Laser-scanned 3D surface with signed deviation colormap where red indicates the laser-scanned surface lies outside the simulated surface and blue indicates the laser-scanned surface lies inside the simulated surface, according to an embodiment of the present invention;

FIG. 11A shows signed deviation histograms comparing best simulated surface geometry using filtered initialization to target geometry, according to an embodiment of the present invention;

FIG. 11B shows a voxelated target surface plotted with colormap of the signed deviation to the DM best simulated surface, where red indicates the simulated surface lies beyond the outside the target surface and blue indicates the simulated surface lies inside the target surface, according to an embodiment of the present invention;

FIG. 12A shows signed deviation histograms (red) comparing laser scan surface to target geometry, normalized to a percentage of the maximum bounding box dimension of the underlying target geometry, according to an embodiment of the present invention;

FIG. 12B shows Laser-scanned 3D surface with signed deviation colormap where red indicates the laser-scanned surface lies outside the target surface and blue indicates the laser-scanned surface lies inside the target surface, according to an embodiment of the present invention;

FIG. 12C shows Photographs of printed and scanned geometries, according to an embodiment of the present invention;

FIG. 13A shows signed deviation histograms (blue) comparing laser scan surface to the DM best simulated surface geometry, normalized to a percentage of the maximum bounding box dimension of the underlying target geometry, according to an embodiment of the present invention;

FIG. 13B shows a Laser-scanned 3D surface with signed deviation colormap where red indicates the laser-scanned surface lies outside the simulated surface and blue indicates the laser-scanned surface lies inside the simulated surface, according to an embodiment of the present invention;

FIG. 14A is a schematic diagram of an optical setup, according to an embodiment of the present invention;

FIG. 14B is a plot of angular deflection versus the hue, according to an embodiment of the present invention.;

FIGS. 14C-14F show results of the tomographic reconstruction procedure after all video frames are captured, according to an embodiment of the present invention;

FIG. 15 shows a visual representation of Schlieren-time segmentation geometry, according to an embodiment of the present invention;

FIGS. 16A-16C show reconstructed n° field slices using independent, moving and interpolation window time-segmentation methods, respectively, according to an embodiment of the present invention;

FIG. 16D shows a triangle helix “.stl” file compared to laser-scanned printed part and the isosurface of isovalue \hat{n}=4×10⁻⁴, according to an embodiment of the present invention;

FIG. 16F shows a thinker “.stl” file compared to laser-scanned printed part and the isosurface of isovalue \hat{n}=2×10⁻⁴, according to an embodiment of the present invention;

FIGS. 16E and 16G are histograms of signed distance of isosurface vertices in (FIG. 16D and FIG. 16F), respectively, from scanned meshes, according to an embodiment of the present invention; and

FIG. 17 shows in the top row color Schlieren images captured during a CAL print of Rodin's ‘Thinker’ and in the bottom row corresponding reconstructed 3D n° fields, according to an embodiment of the present invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed, and other methods developed without departing from the broad concepts of the present invention. All references cited anywhere in this specification are incorporated by reference as if each had been individually incorporated.

The term “light”, and related terms such as optical, are intended to have a broad meaning to include both visible and non-visible portions of the electromagnetic spectrum. For example, “light” can include infrared light and ultraviolet light in addition to including visible light.

An embodiment of the current invention is directed to a continuous and differentiable loss function based on dose penalties. It is formulated to lead to an analytical loss gradient which is amenable to optimization by widely used gradient descent techniques. Along with the introduction of an unconstrained buffer region surrounding the boundary of the 3D object, optimization with the new loss function produced systematic and rapid convergence to dose distributions with sharper spatial gradients of dose at the boundary and higher fidelity to the target geometry both experimentally and computationally, than the prior approach.

In the computed axial lithography (CAL) or tomographic back-projection 3D printing methodology, the goal is to selectively polymerize a 3D object inside a container of photosensitive resin. In particular, only the desired 3D object is polymerized and the material surrounding it remains unpolymerized to facilitate removal of the object from the resin. Because light penetrates through and is partially absorbed by resin which is intended to remain unpolymerized, an optimization approach can be used to find a solution which minimizes exposure to this surrounding resin while also accurately polymerizing the desired 3D object. Given that it is not possible at present to achieve the ideal step change in the dose distribution at the boundary of the 3D object, a large spatial gradient of dose (note: this is separate from the gradient of the loss function referred to later) is desirable because it means that the region outside the 3D object's boundary, although not zero, will receive substantially less dose than the region inside the boundary. This in turn will reduce the amount of rinsing and post processing required to achieve a high-fidelity physical representation of the 3D computational target geometry.

Prior embodiments of CAL printing have used no optimization but required feedback to achieve high fidelity (Loterie et al. 2020 Nature Communications paper) or have used some level of optimization (Kelly et al. 2019 Science paper). The prior optimization approach formulated this problem such that the objective was to satisfy a ‘virtual dose distribution’, i.e., the accumulated light dose should exceed a dose threshold in the region of the 3D target and remain zero outside this region. The loss function, or the function that represents the difference between the trial output and the expected output of the system, was an indicator function whose value was equal to 1 in regions where dose was too high (e.g. high dose outside the target region where it is expected to be zero) and −1 in regions where dose was too low (e.g. low does inside the target region where dose is expected to be greater than the dose threshold) and zero otherwise. This loss function, being non-continuous, was non-differentiable, and thus, a numerical approximation of the gradient of the loss was needed to perform gradient descent optimization. This approach led to results which did not produce a large spatial gradient of dose near the boundary of the desired 3D object to be printed.

According to some embodiments of the current invention, the problem of selectively polymerizing the object in the container of resin is formulated as a penalty-minimization problem rather than a constraint-satisfaction problem as in the prior approach. The penalty is defined as the L1 loss (as in Lp space or Lebesgue space) between the dose value and a particular dose constraint (i.e., the magnitude of the deviation between the dose value and the dose constraint). This was not obvious because the physical problem can be considered a direct physical analog of the computational threshold-constraint-satisfaction model assuming the resin has sufficiently sharp dose-conversion behavior (i.e., the nonlinear response to light dose which occurs when the resin is polymerizing). If the voxel (dose can be represented on a 3D grid of points where each point is called a voxel) resides inside the target there is a dose constraint to which it must be equal or greater than and if the voxel resides outside the target there is a different dose constraint to which it must be less than or equal. Inside the novel buffer region which is a thin region (usually only a few voxels in thickness) surrounding the target region the dose is unconstrained. The buffer region is implemented according to some embodiments to relax the constraints here and allow enforcement of a steeper spatial gradient of dose which was experimentally observed to be more important than enforcement of the exact dose value in this region. According to some embodiments, the penalties are formulated into an analytically differentiable loss function which also has an analytical expression of the gradient. The benefits of having a continuous representation of the loss function (and its analytical gradient) are that many different gradient descent approaches may be readily applied for optimization (e.g., the quasi Newton method LBFGS-B used here) which produce systematic and rapid convergence. Different losses (e.g., L2 loss) and constraint violations may also be used to achieve different characteristics in the optimum reconstructed dose.

The difference between the penalty minimization and dose matching type approaches is encapsulated in the optimization loss function. This may seem like a minor difference, but the loss function is a key aspect of the problem and is what the iterative solver will try to minimize when the projections for 3D printing are generated. In other words, small differences in the loss function could have a major impact on the final projections that are produced by the computational method and will impact the final 3D printed geometry. An advantage of the penalty minimization approach over various flavors of dose matching is that the penalty minimization approach directly allows us to prevent deviations from the desired target geometry. It does so by including a penalty against deviations in the loss function. On the other hand, dose matching approaches only do this in a very indirect manner by trying to match a virtual dose to the desired target geometry. This suffers from an unnecessarily strict requirement compared to the penalty minimization approach. For instance, in penalty minimization, we could allow the dose within the target region to fluctuate provided it was above the threshold for printing. On the other hand, in the dose matching approach, we require that the dose is as close as possible to the virtual target geometry, irrespective of whether it is above or below, and irrespective of how large the deviations are. This leads to a disconnect between the loss function and the printing process, which relies on a gelation threshold. In practice, we have shown how the penalty minimization approach leads to better fidelity compared to a dose matching approach using exemplary geometries. We suspect that the penalty minimization approach will open further avenues of improvement where we can control how we penalize deviations in certain areas: for instance, critical topological links may be assigned a larger weight in the penalty function compared to other regions. By directly controlling the deviations from the target geometry, we hope to achieve much more accurate reproduction of the target geometry compared to dose matching approaches

Another embodiment of the current invention is directed to a color schlieren tomography system for real-time monitoring of 3D refractive index profiles of the patterning material in volumetric additive manufacturing processes (including computed axial lithography). This tomographic imaging system uses a color filter to encode ray deflection information and leverages the angularly separated views to reconstruct 3D index profiles which directly represent polymerization states and provide error information for real-time patterning correction.

Material transformation (polymerization) in volumetric additive manufacturing occurs within the bulk of the materials. The limited mechanical access to the transforming material prevents conventional metrology methods to be applied because they usually require measurements to be made on exposed 2D surfaces. Recently reported heuristic tomographic imaging systems for volumetric additive manufacturing can only perform binary polymerization classification based on manually-picked/manually-learned image threshold values.

In most photopolymers, there is a direct mapping between degree-of-conversion and its refractive index. An embodiment of the current invention is directed to a system and method to quantitatively monitor the 3D polymerization process of the photopolymer through its refractive index change by color Schlieren tomography.

In this system, a broadband observation beam encompassing a wide spectrum of colors is placed perpendicularly to both the patterning beam and the rotation axis while a camera is used to capture colored live video at the end of the beam. The ray deflections of the observation light are encoded in color by applying a colored filter in the Fourier plane of the optical train, thereby enabling information of spatial gradients of refractive index to be extracted from the set of tomographic images and allowing 3D refractive index field to be reconstructed. These colored tomographic images are collected and processed by a computer in real-time to produce a time-series of 3D refractive index reconstruction.

From the reconstructed refractive index fields, the real-time spatial profiles of the degree-of-conversion of the photopolymer can be monitored. These measured 3D polymerization profiles can be used for evaluation of geometric and uniformity errors relative to the fabrication target. This quantitative error information provides a basis for real-time corrections in light intensity projections to compensate for modeling inaccuracies of the optics and material reaction behaviors.

### Some Aspects of the Current Invention are as Follows:

1. The formulation of the computed axial lithography problem (and more generally the physical tomographic reconstruction problem) as a constraint satisfaction problem rather than attempting to satisfy a ‘virtual dose distribution’. This inequality-based approach frees the problem from having to artificially adhere to a dose that does not actually contribute to the physical process of interest (such as 3D printing). Both the 3D printing and radiation therapy cases of the physical tomographic reconstruction problem are best represented as inequality constraint satisfaction problems.
2. The formulation of the inequality constraint satisfaction problem as an optimization of a penalty loss function with tunable weight. The minimization of a loss function associated with constraint violation leads to a near-feasible solution to the constraint satisfaction problem as described in 1 above.
3. The selection of an L1 penalty loss function on the constraint violations in order to encourage spatial sparsity in the constraint violating regions. Other loss functions are also possible.
4. The formulation of an analytical gradient for the penalty loss function. With an analytical gradient, a quasi-Newton method (LBFGS-B) could be used that led to systematic and rapid convergence (as opposed to stochastic gradient descent or gradient-free direct methods).
5. The direct inclusion of discretization and the shape of the projector pixel in the loss function and in the loss function gradient. This allows the specifics of the projection hardware to be carefully incorporated in the calculation without making any extraneous approximations.
6. The optional incorporation of multiple dose inequality constraints in order to limit variability and allow the 3D printed object to physically cross-link over a shorter temporal window. While eliminating the over-constrained situation of attempting to exactly match an underlying dose distribution, the inclusion of multiple inequalities allows for a more controlled dose distribution where it is necessary.
7. The optional inclusion of an unconstrained buffer region to separate the low-dose and high-dose regions. The buffer region can be included through a morphological dilation of the high dose region. The size of the morphological dilating element can be chosen to be less than the physical resolution required. This allows for an additional degree of freedom in the problem formulation and potentially an increased solution space.
8. The optional incorporation of forward and backward light projection which computationally accounts for opaque and arbitrarily attenuating components in the print volume. This allows optimization of a reconstructed dose function with attenuating objects of arbitrary size and number for the special case of overprinting.
9. System and method for target-to-print error evaluation of volumetrically additive manufactured parts. The partis laser scanned and the resultant point cloud is compared to the target surface geometry in terms of the signed distance between the two meshes. The scanned point cloud may also be compared to the computationally optimized dose function.
10. System and method for real-time in-situ imaging of part formation in computed axial lithography printing. The photopolymer polymerization and associated refractive index change is monitored with color Schlieren imaging. The video is processed in real-time to reconstruct tomographically the 3D refractive index change normalized to the background refractive index. This 3D refractive index evolution can be used to update light intensity projections in real-time to correct for process aberrations.

As it can be appreciated from the above paragraphs and the following paragraphs, as aspect of the present invention is to provided a method of producing a three-dimensional object. The method includes providing a volume of radiation-reactive material; illuminating the radiation-reactive material with patterned radiation such that a portion of the volume of radiation-reactive material corresponding to the three-dimensional object reacts to form the three-dimensional object and a remaining portion remains unreacted; and removing the remaining portion of the radiation-reactive material to provide the three-dimensional object. The illuminating of the radiation-reactive material with patterned radiation is based on a minimization of deviations of an energy deposition density below a first threshold in an object zone, an unconstrained buffer zone surrounding the object zone, and a minimization of deviations of energy deposition density above a second threshold in a zone surrounding the buffer zone. The object zone corresponds to a location of the three-dimensional object.

In an embodiment, a loss function is defined as a function of the deviations of the energy deposition density below the first threshold, and of the deviations of energy deposition density above the second threshold. The loss function is minimized to determine the illuminating to be performed.

In an embodiment, the loss function is a continuous differentiable function. In an embodiment, the loss function is as follows:

$${ℒ}_{PM} [ t ] := {ρ}_{1} {\int }_{∼ {V}_{2} [ t ]} ( f ( r ) - {d}_{l} ) dr + {ρ}_{2} {\int }_{∼ {V}_{1} [ t ]} ( {d}_{h} - f ( r ) ) dr .$$

In an embodiment, the radiation-reactive material is a photoactive material. The illuminating of the radiation-reactive material with patterned radiation is an optical computed axial lithographic illuminating.

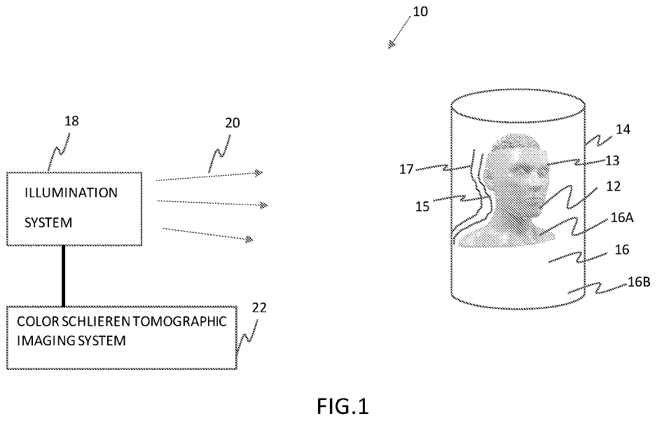

Another aspect of the present invention is to provide a system 10 for producing a three-dimensional (3D) object 12. FIG. 1 is a schematic diagram of the system 10 for producing the three-dimensional (3D) object 12, according to an embodiment of the present invention. The system 10 includes a target volume 14 structured to contain radiation-reactive material 16. The system 10 also includes an illumination system 18 configured to be arranged proximate the target volume14. The illumination system 18 is configured to provide patterned radiation 20 such that a portion 16A of the volume 14 of radiation-reactive material 16 corresponding to the three-dimensional object 12 reacts to form the three-dimensional object 12 and a remaining portion 16B remains unreacted. The illumination system 18 is further configured to provide the patterned radiation 20 based on a minimization of deviations of an energy deposition density below a first threshold in an object zone 13, an unconstrained buffer zone 15 surrounding the object zone 13, and a minimization of deviations of energy deposition density above a second threshold in a zone 17 surrounding the buffer zone 15. The object zone 13 corresponds to a location of the three-dimensional object 12.

In an embodiment, a loss function is defined as a function of the deviations of the energy deposition density below the first threshold, and of the deviations of energy deposition density above the second threshold. The loss function is minimized to determine the illuminating to be performed.

In an embodiment, the loss function is a continuous differentiable function. In an embodiment, the loss function is:

$${ℒ}_{PM} [ t ] := {ρ}_{1} {\int }_{∼ {V}_{2} [ t ]} ( f ( r ) - {d}_{l} ) dr + {ρ}_{2} {\int }_{∼ {V}_{1} [ t ]} ( {d}_{h} - f ( r ) ) dr .$$

In an embodiment, the radiation-reactive material 16 is a photoactive material. In an embodiment, the illumination system 18 is an optical computed axial lithographic illumination system.

A further aspect of the present invention is to provide a method of producing a three-dimensional object 12. The method includes providing a volume 14 of photoreactive material 16; illuminating the photoreactive material 16 with patterned light such that a portion 16A of the volume 14 of photoreactive material 16 corresponding to the three-dimensional object 12 reacts to form the three-dimensional object 12 and a remaining portion 16B remains unreacted; measuring changes in refractive index of the photoreactive material 16 during the illuminating using illumination system 18 including a color schlieren tomographic imaging system 22; determining exposure errors in the volume 14 of photoreactive material 16 during the illuminating and modifying the illuminating to correct at least some of the exposure errors; and removing the remaining portion 16B of the photoreactive material 16 to provide the three-dimensional object 12.

Another aspect of the present invention is to provide a system for producing a three-dimensional object 12. The system includes a target volume 14 structured to contain photoactive material 16; an optical computed axial lithographic illumination system 18 arranged proximate the structured target volume 14; and a color schlieren tomographic imaging system 22 arranged proximate the structured target volume 14. The color schlieren tomographic imaging system 22 is configured to communicate with the optical computed axial lithographic illumination system 18 to provide feedback control thereof.

### Examples

The following examples describe some aspects of the current invention by way of example. The general concepts of the current invention are not limited to only these examples.

A large majority of additive manufacturing (AM) modalities developed to date employ unit material deposition/solidification processes with lower dimensionality than the resultant 3D fabricated part, each typically constructing the part serially with 2D layers. Fused filamentfabrication, selective laser sintering and melting, and stereolithography (SLA) scan layers point-by-point, inkjet and binder jet printing scan layers line-by-line, and digital light processing (DLP) SLA and continuous liquid interface production print entire layers without scanning. Due to their serial nature, many of these methods require support structures, print times can reach many tens of minutes to hours, the staircasing effect of layers can lead to rough surfaces, and anisotropic part mechanical properties may emerge. Advances in 4+ axis motion planning aim to alleviate these problems but more complex machine paths often result in more expensive hardware and more computationally expensive path generation and control. Recent developments in volumetric additive manufacturing (VAM) have taken a different approach, to polymerize simultaneously all points in the part by controlling the 3D superposition of light exposure dose through orthogonal or tomographic techniques. VAM is layer-less and recent implementations have demonstrated support-free fabrication of cm-scale parts having low surface roughness and isotropic mechanical properties in seconds to minutes. Because all points in the part are cured simultaneously, this emerging technique is at the frontier of AM efficiency in terms of resolution and throughput when compared to the preceding layer-by-layer methods, and maturation of the hardware and computational methods supporting VAM will help to establish further and even expand its capabilities.

Tomographic VAM or Computed Axial Lithography (CAL) proposed by Kelly et al. derives many of its working principles from computed tomography (CT), an important non-invasive medical and non-destructive industrial 3D imaging modality. In conventional CT imaging, X-rays are transmitted at a series of angles through a static subject, with the attenuation being recorded after transmission as a series of 2D projections in a 3D data set (radius, height, angle). The computational tomographic reconstruction of the subject's 3D attenuation map (X, Y, Z) is typically realized by the Fourier slice theorem and various other iterative or direct algorithms which have no particular physically established constraints on the projections.

We systematically investigate the more challenging inverse problem of physical tomographic construction in the context of CAL. In this case, physical time-multiplexed projections of visible or ultraviolet radiation are absorbed by a relevant chemical photo-initiator. The physical radiation source naturally leads to a positivity constraint on the projection space, and typically an upper bound as well due to limitations on the maximum intensity from the radiation source.

The goal of the optimization is to pre-calculate a spatial distribution of intensity such that after projection over angles, the accumulated energy dose is below a certain threshold in ‘background’ regions to prevent solidification and above a (higher) threshold in ‘target’ regions to solidify the resin and lead to selective photopolymerization. The target and background dose requirements are specified as inputs to the mathematical problem and the set of calculated intensities (of finite nonnegative range limited by DLP dynamic range) is the desired output. Previous approaches have used a heuristic finite difference gradient descent method based on anomalously printed regions or have used only filtering and no optimization to generate the projections. In this work we have systematically studied and experimentally demonstrated analytical gradient descent optimization approaches based on meaningful loss functions. In order to arrive at a useful optimization loss function, we note that the main requirement for fabrication of the desired geometry consists of the dose exceeding a threshold. This is an inequality constraint. We also note how this is in some sense the inverse problem of imaging, since the desired output of the calculation is the intensity in projection space (radius, height, angle), whereas the target is the known dose distribution in real space. Therefore, the loss function needs to be defined over the dose space but gradient descent is performed in projection space.

To summarize, some novel features of embodiments of the present invention are:
1. a principled gradient descent optimization approach for CAL projection generation;
2. a formal connection to the heuristic finite difference approach used by Kelly et al. in a prior demonstration of CAL;
3. the demonstration of high-fidelity volumetric printing, according to the metrics presented here;
4. a method for optical metrology of printed constructs for empirical verification of fidelity;
5. meaningful metrics for quantitative comparison with a heuristic optimization approach (both for the computational optimization process as well as the empirical prints).

First, we mathematically describe the forward model from projection space (radius, height, angle) to 3D dose distribution. Then, we conceptualize the inverse problem in terms of dose penalty minimization in different regions of the dose distribution and continue to derive the loss function. A second inverse problem formulation, meant to resemble a heuristic dose matching approach, is also described as a point of comparison. Computational results are then evaluated using various dose distribution metrics and experimental print fidelity is measured with 3D optical metrology.

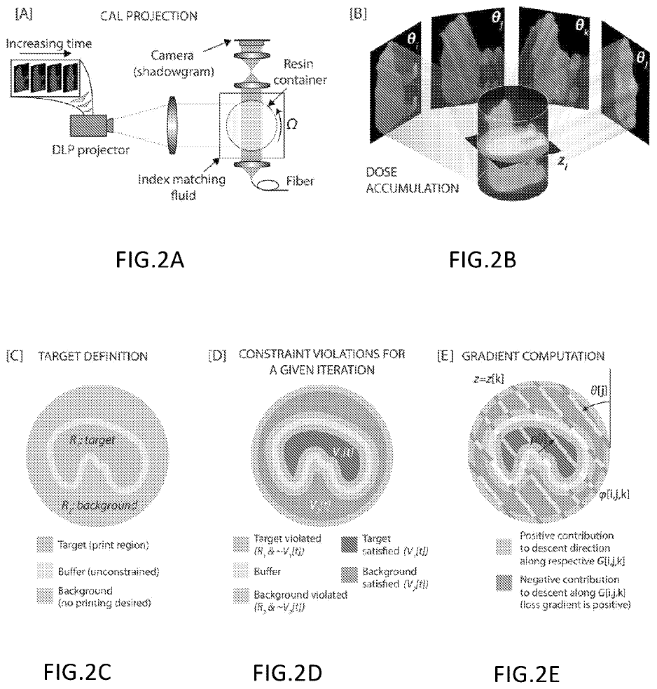

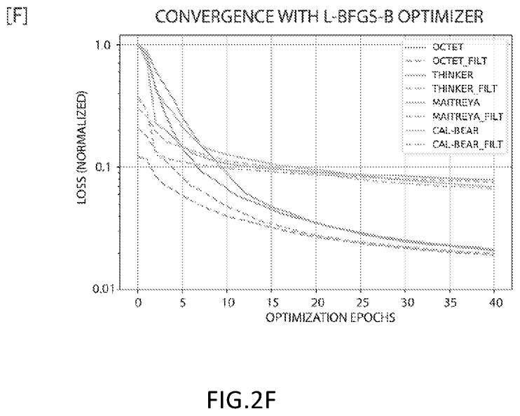

FIG. 2A is a schematic diagram of a Computed Axial Lithography (CAL) system, according to an embodiment of the present invention. FIG. 2B isa schematic representation of a 3D dose formation that occurs through the integral of projections across angles as the resin container rotates (example back-projections shown here for angles θᵢ, θⱼ, θₖ, θₗ), with higher accumulated dose where higher intensity projections locally overlap, according to an embodiment of the present invention. FIG. 2C is a schematic representation of the target, buffer and background regions that are derived from the print geometry, according to an embodiment of the present invention. FIG. 2D is a schematic representation of the target illumination at every iteration, violating regions are determined based on the dose distribution and constraint requirements, according to an embodiment of the present invention. FIG. 2E is a schematic representation showing the loss gradient for the update determined based on violating regions, according to an embodiment of the present invention. Regions with too little dose where we require printing contribute positively to the gradient descent and vice versa for high dose in the background. The gradient is determined for each pixel in projection space φ(i, j, k). FIG. 2F are various optimization curves showing the loss versus optimization epochs, according to an embodiment of the present invention. Loss curves using a quasi-newton L-BFGS-B optimizer on four different 3D geometries are compared using two initialization conditions. Solid lines are for the unfiltered Radon initialization, and dashed are for filtered (positivity constrained) projection initialization. The latter (dashed lines) show less loss at initialization in all four considered geometries. However, both initializations lead to nearly identical converged loss after 40 optimization epochs. It is noted that the loss is normalized individually for each geometry, to the starting loss when using unfiltered Radon transform as initialization.

Forward model: In order to describe the forward model, we use mathematical notation consistent with Tretiak and Metz. The projection intensity in irradiance (flux density units) is denoted here as g(ρ, θ, z). The integral projection operator that transforms projection intensity to dose is denoted as T*_{-α}[g]. The notation is consistent with the fact that it performs the mathematical adjoint (transpose) of the exponential Radon transform, which is denoted as T₋ₐ[f] where f(r, z) is the 3D dose distribution. The former integral projection operator performs an integration over angle of the projector intensity and produces the 3D dose distribution. Here, the subscript-a indicates attenuation according to the negative exponential Beer-Lambert law by an attenuation constant of α per unit length. We consider a case in which the print medium is rotating at a constant angular velocity Ω, and a video is projected into it using an external projector. This is consistent with the apparatus described in Kelly et al. The 3D dose distribution f(r, z) in energy density per unit volume is then given by the formula:

$$f ( r , z ) = \frac{α {N}_{r}}{Ω} ( {T}_{- α}^{*} [ g ] ( r , z ) ) = \frac{α {N}_{r}}{Ω} {\int }_{θ = 0}^{θ = 2 π} g ( ρ = r \cdot \hat{θ} , θ , z ) {e}^{- α r \cdot θ ⊥} d θ \qquad ( 1 )$$

where Nᵣ is the number of rotations of the resin container (FIG. 2A), r=x\hat{x}+yŷ, \hat{θ} is the unit vector \hat{x} cosθ+ŷ sin θ and θ⊥ is the unit vector \hat{z}×\hat{θ} along the axis of rotation. The integral expands the back-projection operator as an integration over azimuthal angle. The coordinate system and unit vectors used in the formula are shown in FIG. 2D.

Given this forward model, we would like to generate an optimal set of projections g(ρ, θ, z) that achieves the stated goal of exposing the target geometry, but also maintains a low dose in the background where no solidification is desired. A schematic of the CAL system used to print the objects shown in Section 4 is depicted in FIG. 2A.

Inverse problem formulation: Here, we will describe how we can define a principled loss function to penalize deviations from the target geometry. This loss function can then be rigorously minimized with respect to the projections, in order to obtain a set of optimal projections to deposit the desired dose. This leads to the penalty minimization approach. We describe how the approach previously described by Kelly et al. is formally a heuristic of one possible penalty minimization approach in the supplementary materials. We will also describe an intuitive alternative for comparison of the penalty minimization approach, namely a dose matching approach. Lastly, we will describe some of the details of the optimization algorithm.

Penalty minimization: For perfect printing of the desired geometry, we require that the accumulated real space dose f(r, z) exceeds a solidification dose dₕ in the target region R₁ and remains below it in the surrounding regions. While depletion of oxygen is linear in the accumulated energy dose, the polymer cross-linking process that follows is sharply non-linear and consumes approximately 10-20% of the total energy dose based on empirical observations of print progression. In order to accommodate for the cross-linking dose, we require that the dose in background regions R₂ is below a threshold d₁ that is at least 20% below the target solidification dose dₕ. We may also potentially desire that the target region dose remains within a specific bound (dₕ, dₘₐₓ), so that the entire object is fabricated within a short temporal window and there is minimal refractive index change in the resin during the fabrication window. These requirements may be succinctly expressed as below:

$${R}_{1} : {d}_{max} \geq f ( r , z ) \geq {d}_{h} \qquad ( 2 )$$

$${R}_{2} : f ( r , z ) \leq {d}_{1} . \qquad ( 3 )$$

The regions R₁ and R₂ need to be defined carefully. We could define R₁ to be the volume of the desired object and R₂ as its complement within the resin vial. There is some benefit to defining R₁ as a slightly eroded version of the target object, and R₂ as an eroded version of the complement, so that there is an unconstrained spatial region separating R₁ and R₂ which we term the ‘buffer region’. An example is shown in FIG. 2C. The target region is shown in a deeper shade of blue, the unconstrained region is a lighter shade. The remaining part of the resin volume becomes the background and is displayed in orange.

The main rationale for leaving an unconstrained buffer region between R₁ and R₂ relates to discrete voxelization of the problem. The voxelated representation of the “.stl” face and vertex format is necessary so that we may apply the discrete Radon transform and obtain projection images through iterative optimization which are again pixelated at the level of the projector. The voxelated representation (and the “.stl” from which it is derived) have sharp spatial boundaries which result in infinite spatial frequencies in the Fourier transform. These frequencies can lead to aliasing artifacts because the discrete Radon transform is inherently Nyquist limited. Nevertheless, the optimization method needs clear separation between distinct regions, but at the same time we would like to avoid jagged features related to discretization. The unconstrained buffer region has been introduced to allow the dose to smoothly transition from high (target) to low (background), thus inducing a low-pass anti-aliasing filter effect. This is expected to lead to smoother surfaces than attempting to optimize towards an exact voxelated geometry where we would penalize voxels directly adjacent to the voxelated surface.

In setting up the computational problem, the erosion operations can be achieved through conventional morphological erosion operations with a cubical structuring element. Since the dose is unconstrained in the buffer region, we are admitting a resolution worse than the width of the buffer region. Consequently, we have kept the width of the buffer region to be small at two voxels of the computational representation of the target volume. Employing a cubical structuring element with side length of three voxels leads to one voxel of buffer for target and background regions each, and accordingly, to two voxels of total buffer region width. Equal erosion of the target and background regions was performed for the current study since it is expected to lead to best adherence to the underlying geometry. Note that the penalties on dose deviations are equal in target and background regions in this work (β₁=β₂).

The loss function can then be defined as either least absolute deviation L₁ or least squares deviation L₂ loss, integrated over the constraint violating regions of the geometry. The L₁ loss function may be preferable since it produces the same gradient irrespective of the magnitude of the loss, leading to violations that are sparser. Henceforth, we assume that there is no maximum dose constraint in the print region R₁ without significant loss of generality. By giving up the maximum dose constraint, we are potentially losing the advantage of finishing printing within a short time window. However, there could be a detrimental impact on the print fidelity from requiring very tight dose constraints, since we are allowing for lesser freedom in the dose distribution in the upper range.

Let us assume that for a particular optimization epoch t, the constraint satisfying region within the target print region R₁ is V₁[t]: this is the region where the real space dose f(r) exceeds the solidification threshold dₕ. Then the region where the constraint is violated is given by the volume intersection: R₁∩¬V₁[t], which we denote as ˜V₁[t]. Note that ¬V₁[t] indicates all regions where solidification dose is below threshold dₕ. Similarly, if the dose exceeds the lower limit d₁ within R₂, we have a constraint violating region R₂∩¬V₂[t], which we will refer to further as ˜V₂[t]. Then, the loss function is described by integrals of the deviation from constraint over the respective constraint violating regions ˜V₁[t] and ˜V₂[t]:

$${ℒ}_{PM} [ t ] := {ρ}_{1} {\int }_{∼ {V}_{2} [ t ]} ( f ( r ) - {d}_{1} ) dr + {ρ}_{2} {\int }_{∼ {V}_{1} [ t ]} ( {d}_{h} - f ( r ) ) dr . \qquad ( 4 )$$

In other words, where we desire solidification, but the dose is too low, we have a penalty proportional to the difference dₕ −f(r), and respectively for where solidification is not desired (˜V₂[t]). The index t denotes the particular iteration for which the loss is calculated. For now, we assume that both the target and background penalties need to be weighted equally: ρ₁=ρ₂=1, and then express the real space dose distribution f(r) in terms of the continuous projection space intensity through the attenuated back-projection operation (substituting equation (1)):

$${ℒ}_{PM} [ t ] := {\int }_{∼ {V}_{2} [ t ]} \{ \frac{{N}_{r} α}{Ω} ( {T}_{- α}^{*} [ g ] ( r ) ) - {d}_{1} \} dr + {\int }_{∼ {V}_{1} [ t ]} \{ {d}_{h} - \frac{{N}_{r} α}{Ω} ( {T}_{- α}^{*} [ g ] ( r ) ) \} dr . \qquad ( 5 )$$

Differentiating with respect to the projector weights G_{i,j,k} (by substituting equation S1, see Section S2 for details on discretization of the continuous projection space intensity function g(ρ, θ, z)) and using the linearity of the back-projection operator, we find that the gradient of the loss at a specific iteration tis given by:

$$\frac{\partial }{\partial {G}_{i , j , k}} {ℒ}_{PM} [ t ] := {\int }_{∼ {V}_{2} [ t ]} \frac{{N}_{r} α}{Ω} ( {T}_{- α}^{*} [ {ϕ}_{i , j , k} ] ( r ) ) dr - {\int }_{∼ {V}_{1} [ t ]} \frac{{N}_{r} α}{Ω} ( {T}_{- α}^{*} [ {ϕ}_{i , j , k} ] ( r ) ) dr \qquad ( 6 )$$

where φ_{i,j,k} represents a pixel in the discretized projection space.

In other words, the gradient with respect to the power of a projector pixel is given by the real space integral of the back-projection of that specific pixel. This is illustrated in FIG. 2E for several projection space pixels at the same θⱼ and zₖ, but at varying radii ρᵢ. Regions for which the descent direction integrand is positive (green) and negative (red) are consistent with the intuition that we iteratively increase intensity for those pixels where we want additional material and we reduce intensity where there is undesired material. Note that we ignore the variation of the violated volumes (with respect to the projector intensity) in the loss gradient, since the variation will occur at the boundaries of the violated volume where the integrand of the L₁ loss is expected to be close to 0 due to continuity. In the following paragraphs, we refer to ˜V₁[t] as regions with type 1 violation (dose too low), and ˜V₂[t] as regions with type 2 violation (dose too high). We refer to this method as the penalty minimization (PM) method, as seen in the subscript for the loss [symbol] _{PM}[t]. Note that this loss function is defined only over violating regions of the dose, a non-linear Boolean operation on the spatially continuous dose distribution. The violating regions are updated after each iteration of the optimization, based on the current iteration dose distribution.

Dose matching method: As a point of comparison, we also contrast the penalty minimization method with a heuristic approach that directly attempts to match the tomographically constructed dose to a ‘virtual target dose’ distribution that mimics the target geometry. This approach will be referred to as the dose matching (DM) technique. A direct L₂ loss function of normalized 3D dose to the target geometry leads to a convex problem with a known globally optimal solution. However, this was empirically found to be typically a much poorer solution than is arrived at by incorporating the non-linearities in the resin response in the forward model. We incorporate such a non-linearity in the forward model by using a sigmoid function to clamp the physical dose distribution. This clamped distribution is considered as the object distribution function F(r) at a specific optimization epoch t. The sigmoid non-linearity threshold is given by the solidification threshold dₕ. This non-linear dose formation model can then be expressed as:

$$F ( r ) [ t ] := σ ( \frac{{N}_{r} α}{Ω} ( {T}_{- α}^{*} [ g ] ( r ) ) - {d}_{h} , δ ) \qquad ( 7 )$$

where the two parameter sigmoid function used is:

$$σ ( z , δ ) = 1 / ( 1 + {e}^{\frac{- z}{δ}} ) .$$

The parameter δ controls the slope (sharpness) of the sigmoid function. The loss function is then defined as an L₁ loss of the ‘object distribution’ F(r)[t] with respect to the desired target geometry Θ(r). Note that the desired target is a discontinuous Boolean function of space. The loss function for optimization (at a specific epoch t) is then expressed as the following sparsifying L₁ loss:

$${ℒ}_{PM} [ t ] := \int \vert F ( r ) [ t ] - Θ ( r ) \vert dr = \int \vert σ ( \frac{{N}_{r} α}{Ω} ( {T}_{- α}^{*} [ g ] ( r ) ) - {d}_{h ,} δ ) - Θ ( r ) \vert dr . \qquad ( 8 )$$

The intention is to produce a 3D dose distribution that will solidify to closely resemble the underlying target geometry Θ(r). The gradient of the loss function with respect to projector pixel intensities is given by the following analytical formula:

$$\frac{\partial }{\partial {G}_{i , j , k}} {ℒ}_{PM} [ t ] := \int \frac{1}{δ} σ ( z [ t ] , δ ) ( 1 - σ ( z [ t ] , δ ) ) \times [ \frac{{N}_{r} α}{Ω} ( {T}_{- α}^{*} [ {ϕ}_{i , j , k} ] ( r ) ) ] sgn ( F ( r ) [ t ] - Θ ( r ) ) dr \qquad ( 9 )$$

$$z [ t ] = [ \frac{{N}_{r} α}{Ω} ( {T}_{- α}^{*} [ g ] ( r ) ) - {d}_{h ,} ] \qquad ( 10 )$$

The loss function gradient is with respect to specific projector pixel intensities, and has the same dimensions as the projector space, as in equation (6). The formula has been derived by taking the derivative of the loss gradient in Equation (8) with respect to a single projector's intensity G_{i,j,k}. The derivatives of the sigmoid function and the absolute value function have been substituted, where sgn( . . . ) refers to the sign function. Equation (10) is the argument of the sigmoid function. This loss function and its analytical gradient can then be used to perform optimization for the optimal projector pixel intensities. The sigmoid hyperparameter δ (in energy dose units) may require tuning on a resin level and was kept fixed for this study at a value for which all the geometries produced good results for the filtered initialization (FIG. 5B).

We note that the projection space vector to be optimized G_{i,j,k} will contain on the order of 1-10 million points, and potentially more depending on the application and fidelity to underlying target needed. We would ideally like to maintain a projector pixel size and angular resolution that satisfies the Nyquist sampling theorem with respect to the spatial frequency content we would like to capture in the model. If the spatial sampling along radius and height are too coarse, this will lead to aliasing in frequency space. If the angular sampling is too coarse, this will lead to streaking artifacts in real space that correspond to spatial aliasing. In the optimization procedure, we use an anti-aliasing filter to prevent issues arising from sampling, since the number of pixels is limited by computational capability. The number of voxels scales to the third order with resolution, and each optimization step requires a matrix-vector multiplication on a vector of these voxels. As a tradeoff, we have used an angular discretization of 1 degree and approximately 100 spatial points along radius and height. This led to a computationally large but not intractable problem for CPU computation. By definition, the consequence of using a larger voxel size with an anti-aliasing filter is that we will not be able to represent the finest features. This has been recognized and the comparison of accuracy metrics is made to the voxelized design as opposed to the exact steoreolithography file description of a target geometry. We also note that the loss function and loss gradient are calculated using integrals of dose-related functions in the real space R. These integrals are currently evaluated using a simple Riemann sum of the voxelated dose distribution.

For such a typical computational inverse problem with 1-10 million parameters, it is impractical to form the Hessian matrix or use true second order methods in optimization. Therefore, we have relied on the quasi-Newton L-BFGS-B algorithm which forms successively improved approximations of the inverse Hessian as additional epochs accumulate. This method can be applied to compare the DM and PM methods since both have analytical gradients available. The method also has minimal additional hyperparameters and enables a one to one comparison of the two methods of interest.

There are a few other important aspects of the optimization procedure. Firstly, we need to make an appropriate choice of the initial vector Go ideally one that satisfies the projection space positivity and max constraints. There are two obvious ways to do this. Firstly, we could simply apply the exponential Radon transform (T_{α}[f_{T}](ρ, θ, z)) on the target dose distribution(f_{T}) and scale the projections until the max constraint is satisfied. This will satisfy the positivity constraint by definition. Alternately, we could also filter the projections using the same filter that would invert the Radon transform; e.g., the Ram-Lak or Shepp-Logan filters are used in CT, typically. However, these filtered projections (g_{F}(ρ, θ, z)=h_{F}(ρ)*g(ρ, θ, z)) invariably lead to negatives in the result since the filter impulse response h_{F}(p) has negative values. A simple procedure to overcome this issue is to positivity-constrain the filtered Radon transform g_{F} and use that as the initialization for the optimization routine. This initialization choice was empirically found to lead to faster convergence and less initial loss in the penalty minimization method. The optimization was terminated on the basis of maximum number of epochs (40) or a tolerance criterion based on both the loss function and its gradient.

We also note that some physical parameters associated with the problem definition can be scaled together: dₘₐₓ, dₕ,dₗ, Nᵣ, Gₘₐₓ (maximum projection intensity, Section S2). In the results that follow, we have chosen to eliminate the maximum dose constraint dₘₐₓ and found that dₕ=0.9, dₗ=0.5 was a reasonable choice of parameters for PM optimization when Gₘₐₓ was limited to 255, corresponding to 8 bits. For DM optimization, we use dₕ=dₕ₀+δ where dₕ₀=0.9 is the same as dh used in PM optimization and δ=0.05 was found to give the least loss. This is a heuristic and the effect that the width of the sigmoid function has on optimization could be investigated further in future work. We expect that the maximum dose constraint will not have a significant effect on the optimization since dose distributions within the print region appear to be fairly narrow. This may need to be explored carefully for the limiting case in which the maximum dose constraint approaches the solidification dose constraint dₕ. The transfer function from the 8-bit projector input to the power output was empirically found to be very closely linear with zero intercept, and has been absorbed into the 3D dose. The particular physical setting of the problem will determine the exact scale of the physical parameters, but for the projector and resin combination used here, the above parameters were found to be effective. In the current implementation, we have left Nᵣ as a floating parameter, and determined Ω based on the maximum frame rate of the video projector. The optimization is performed on a single rotation of the projector, assuming the above parameter choices. The number of rotations is adjusted case by case and is typically above 10, so that the precise number becomes less relevant. In future work, we expect to perform some form of multi-objective optimization, in order to minimize the total print time, while satisfying the stated dose constraints.

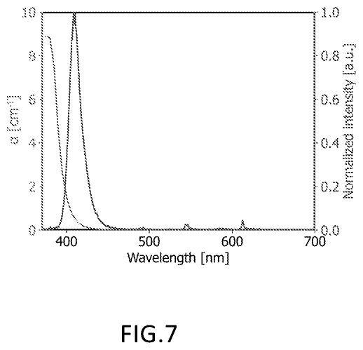

Finally, it should be noted that we describe the PM optimization method, generally, as if attenuation is nonnegligible and without restriction to a particular physical scale. However, in the experiments that follow we used a resin formulation with low attenuation α=0.05 cm⁻¹ which corresponds to only 5% light intensity decay at the center of the 2 cm diameter resin container used (FIG. 7). Therefore, in the optimization we have assumed negligible exponential absorption which enabled the use of traditional forward and backward projection routines from CT. Additionally, while the scalability of the CAL process is an important consideration, it is not in the scope of this work and we direct the reader to the supplementary materials of Kelly et al. specifically S21 Relationship between printing speed and spatial resolution, for a detailed analysis. FIG. 7 shows the absorption spectrum of the resin formulation in units of inverse length (left axis) and the normalized light intensity spectrum of the projector (right axis), according to an embodiment of the present invention.

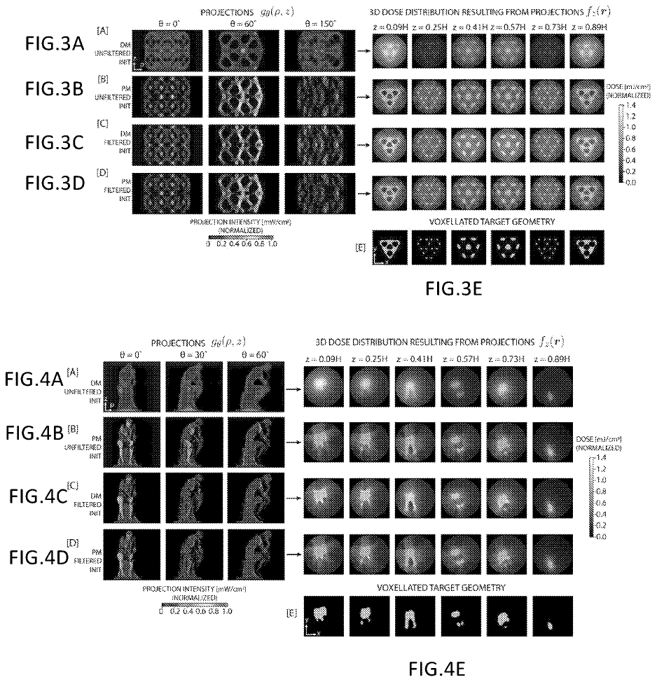

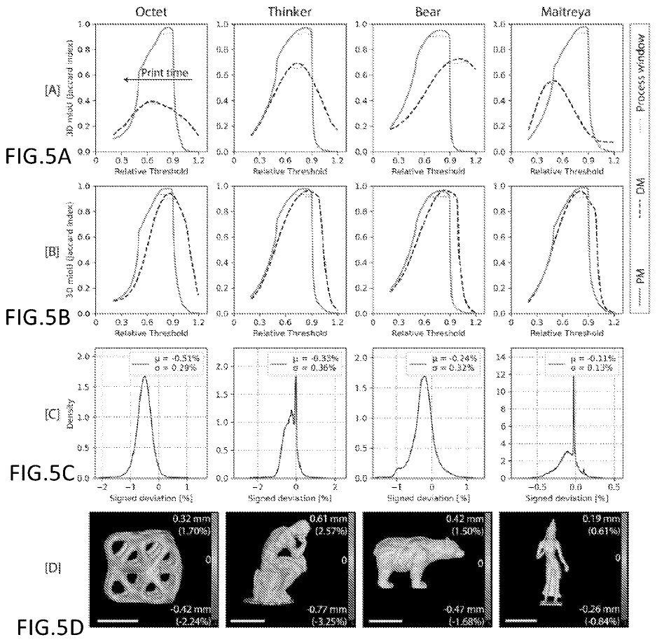

Results and discussion: We attempted projection optimization and printing of four exemplary 3D geometries, derived from publicly available stereolithography files. These geometries are descriptively titled ‘Octet’, ‘Thinker’, ‘Bear’, and ‘Maitreya’. PM-based fabrication was performed on all four geometries, while DM was additionally performed on the Octet and Thinker geometries for an end-to-end experimental comparison of the PM and DM methods. Here, we first compare the two approaches using computational results from the optimization. A snapshot of the computational results is shown for the Octet and Thinker geometries, for which both PM and DM approaches were experimentally attempted. The comparison, including several projector intensity images g_{θ}(ρ, z) and dose distribution slices f_{z}(r) for the Octet and Thinker geometries are shown in FIGS. 3A-3E and 4A-4E, respectively.

FIGS. 3A-3E show octet geometry computational projection and dose distribution comparison between different initializations and optimization methods, according to an embodiment of the present invention. FIG. 3A shows a converged projection intensity (at three exemplary angles) for DM with unfiltered initialization, with resulting calculated 3D dose distribution shown on the right in the same row, according to an embodiment of the present invention. FIG. 3B shows a converged projector intensity for PM with unfiltered initialization, with resulting 3D dose on the right, according to an embodiment of the present invention. FIG. 3C shows a converged projection intensity same as FIG. 3A but with Shepp-Logan filtered (positivity-constrained) initialization, according to an embodiment of the present invention. FIG. 3D shows a converged projection intensity same as FIG. 3B, but with filtered initialization as in FIG. 3C, according to an embodiment of the present invention. FIG. 3E shows the target geometry at exemplary Z-slices, according to an embodiment of the present invention.

FIGS. 4A-4E show thinker geometry computational projection and dose distribution comparison between different initializations and optimization methods, according to an embodiment of the present invention. FIG. 4A shows a converged projection intensity (at three exemplary angles) for DM with unfiltered initialization, with resulting calculated 3D dose distribution shown on the right in the same row, according to an embodiment of the present invention. FIG. 4B shows a converged projection intensity for PM and unfiltered initialization, with resulting 3D dose on the right, according to an embodiment of the present invention. FIG. 4C shows a converged projection intensity same as FIG. 4A but with Shepp-Logan filtered (positivity-constrained) initialization, according to an embodiment of the present invention. FIG. 4D shows a converged projection intensity same as FIG. 4B, but with filtered initialization as in FIG. 4C, according to an embodiment of the present invention. FIG. 4E shows the target geometry at exemplary Z-slices, according to an embodiment of the present invention.

All four combinations are compared computationally, arising from the two optimization methods (PM/DM), and the projection initialization (filtered/unfiltered). As observed in the dose distribution on the right of panel [A] for both the geometries, the converged projections arising from DM initialized with unfiltered back-projections are low in intensity contrast and lead to low dose contrast between R₁ and R₂. Initialization with filtered projections gives some improvement. In contrast, PM-optimization produces sharp projections, irrespective of initialization, that produce accurate and uniform dose distributions with minimal dose ‘hotspots’ which are discussed later in this section.

Further comparing the dose distributions, for both the Octet and Thinker geometries it can be observed that the z-slices with more material (e.g. Z=0.09H in FIGS. 3A-3E and Z=0.09H in FIGS. 4A-4E) have very high relative dose in the unfiltered initialization using DM optimization. However, the z-slices with less material (e.g. Z=0.25H in in FIGS. 3A-3E and Z=0.57H in in FIGS. 4A-4E) have lower relative dose and tend to have type 1 violations. This discrepancy is resolved in the dose distributions arising from the PM-optimized projections irrespective of initialization. We use the Jaccard similarity index or mean intersection over union (mIoU) as an accuracy metric and compute this versus a threshold sweep, as shown in FIGS. 5A-5D.

Print process simulation: We calculate the fidelity of the thresholded accumulated dose to the desired target geometry as a function of the dose accumulation time. The relative threshold is inversely proportional to the print time. FIG. 5A is a plot of mIoU vs. dose threshold for projections generated via unfiltered initialization (for both DM and PM approaches), according to an embodiment of the present invention. FIG. 5B is a plot of mIoU vs. dose threshold as in FIG. 5A, but for projections generated by Shepp-Logan (positivity constrained) filtered initialization, according to an embodiment of the present invention. FIG. 5C show a simulated signed deviation histogram between target and best simulated geometries using PM optimization and filtered initialization, according to an embodiment of the present invention. FIG. 5D shows a voxelated target geometry with signed deviation colormap where red indicates the simulated surface lies outside the target surface and blue indicates the simulated surface lies inside the target surface, according to an embodiment of the present invention. Octet 3σ=0.16 mm, Thinker 3σ=0.26 mm, Bear 3σ=0.27 mm, and Maitreya 3σ=0.12 mm. Scale bars=10 mm. All the results shown here are based on computational simulation of the print process.

We define the mIoU in the context of VAM as the number of print region voxels in the intersection of the predicted print geometry and the reference geometry divided by the number of voxels in the union of the predicted and reference file. The voxelated geometry is derived from the .stl description. These voxelated geometries are shown in FIG. 5D, and have some associated geometries. In other words, if #denotes cardinality, [symbol] _{ref} is the set of voxels in the reference geometry and [symbol] ₚᵣᵢₙₜ is the set of voxels in the printed geometry, the mIoU is the quotient

$$\frac{\# ( {ℛ}_{ref} ⋂ {ℛ}_{print} )}{\# ( {ℛ}_{ref} ⋂ {ℛ}_{print} )} .$$

The reference geometry for the mIoU vs. threshold evaluation is a voxelated version of the true target geometry. Note that the target geometry is originally specified as a set of vertices and faces in a standard “.stl” file. The voxelated geometry is derived from the “.stl” description. These voxelated geometries are shown in FIG. 5D, and have some associated staircasing artifacts due to the Cartesian voxel definition. In order to determine the 3D mIoU metric, the predicted print geometry is defined using a single threshold that is varied with respect to the 3D dose distribution. Voxels that exceed this energy threshold are printed, with a geometry being defined for each individual threshold value. In the printing process, we think of sweeping from the right to left in a geometry being defined for each individual threshold value. In the printing process, we think of sweeping from the right to left in the curves in FIG. 5A and FIG. 5B in order to mimic the dose accumulation as print time increases (or as relative threshold reduces with respect to the existing dose distribution). From this sweeping procedure, we observe that PM (red curve) results in superior mIoU in nearly all cases exceeding 0.95 for all geometries and initializations (Table 1). These results exceed those presented for the Thinker geometry by Kelly et al. We attribute the improved mIoU metric to the use of principled optimization methods (based on a particular loss function) in this work as opposed to heuristic finite difference based gradient descent iteration in the earlier work. The optimization approach used here also allows for faster convergence since it is a quasi-Newton approach.

Simulated print result mIoUs on exemplary geometries. Opt=PM refers to penalty minimization, Opt=DM refers to dose matching, Init=0 refers to unfiltered initialization, Init=1 refers to Shepp-Logan (positivity-constrained) initialization.

TABLE 1

| | Opt = PM, | Opt = DM | Opt = PM, | Opt = DM |
|---|---|---|---|---|
| Geometry | Init = 0 | Init = 0 | Init = 1 | Init = 1 |
| Octet | 0.973 | 0.397 | 0.980 | 0.942 |
| Thinker | 0.968 | 0.692 | 0.976 | 0.963 |
| Bear | 0.952 | 0.730 | 0.961 | 0.966 |
| Maitreya | 0.966 | 0.560 | 0.986 | 0.957 |

We also computationally evaluate the signed deviation from the target geometry to the ‘best’ geometry (as defined by the isosurface resulting from the dose threshold that produces the maximum mIoU). This is done for the geometries with filtered initialization since DM is clearly worse with unfiltered initialization. The mesh-to-mesh signed deviation is calculated as a percentage of the maximum bounding box dimension for each geometry. FIG. 5C shows the signed deviation histograms of the data. The color mapping FIG. 5D shows a view of the local deviation values, mapped onto the target geometry surface. Where the surface of the computationally reconstructed geometry deviates outwards from the target surface, the color is red and vice versa for blue. The maximum 3σ deviation across the four geometries presented is 0.27 mm (for the chosen physical scale of the problem). The histograms show that the deviations expected from computation are typically below 2% of the maximum bounding box dimension for the chosen geometries. The theoretical maximum surface deviation is important to establish as a computational limitation, since the surface deviation of the empirical result will be worse due to non-idealities which are not modeled in the optimization procedure. The signed deviations are also calculated for Octet and Thinker DM-optimized simulation dose distributions for a baseline comparison (FIGS. 11A-11B). The minimum 3σ deviation is 0.33 mm, indicating that PM produces more accurate dose distributions even at the computational level which is in agreement with the mIoU curves shown in FIG. 5B.

FIGS. 11A-11B show a DM-optimized simulated signed deviation, according to an embodiment of the present invention. FIG. 11A shows signed deviation histograms comparing best simulated surface geometry using filtered initialization to target geometry, according to an embodiment of the present invention. FIG. 11B shows a voxelated target surface plotted with colormap of the signed deviation to the DM best simulated surface, where red indicates the simulated surface lies beyond the outside the target surface and blue indicatesthe simulated surface lies inside the target surface, according to an embodiment of the present invention. Octet 3-σ=0.51 mm and Thinker 3-σ=0.33 mm. Scale bars=10 mm.

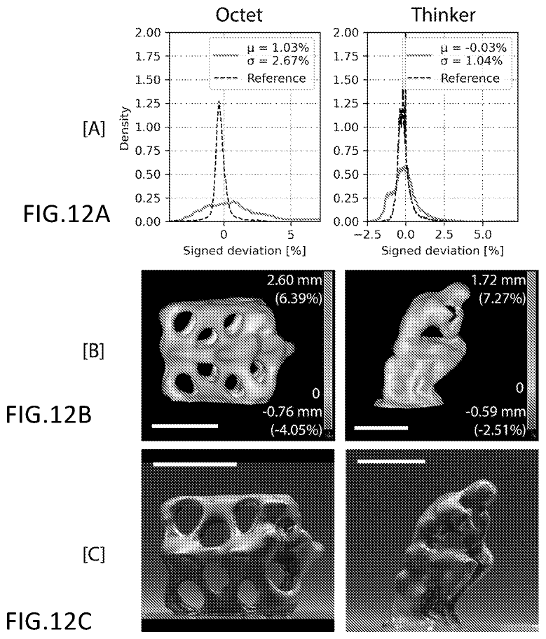

FIGS. 12A-12C show Laser scanning measurement of both DM-optimized geometries compared to reference geometries, according to an embodiment of the present invention. FIG. 12A shows signed deviation histograms (red) comparing laser scan surface to target geometry, normalized to a percentage of the maximum bounding box dimension of the underlying target geometry, according to an embodiment of the present invention. The reference histogram (dashed black) shows the comparison of the simulated prints at the optimal threshold for peak mIoU to the target geometry (FIG. 5C). FIG. 12B shows Laser-scanned 3D surface with signed deviation colormap where red indicates the laser-scanned surface lies outside the target surface and blue indicates the laser-scanned surface lies inside the target surface, according to an embodiment of the present invention. FIG. 12C shows Photographs of printed and scanned geometries, according to an embodiment of the present invention. Note: printed parts are painted black to reduce reflectivity and improve laser scannability. Scale bars=10 mm.

The accuracy of the print method is not the only metric of importance as far as expected empirical print quality is concerned. We are also concerned with the range of dose thresholds for which a reasonably good print quality (mIoU) can be achieved. A range of acceptable dose thresholds allows the empirical print dose to be off slightly from the optimal value for peak mIoU, without resulting in a significant degradation to print quality. We use the ‘simulated process window’ as a convenient metric for capturing the robustness of a particular projection recipe. With reference to FIGS. 5A-5D, we define the process window (shown using dashed teal lines near the peak of each mIoU curve) as the range of thresholds over which the mIoU exceeds 0.95 times the peak mIoU achieved over all thresholds. This range of thresholds is then divided by the threshold at which peak mIoU is achieved, in order to provide a normalized metric for comparison across geometries, as presented in Table 2. A wider process window indicates that the geometric conformity to the target is not degraded for a wider range of doses. At first glance, the process windows for unfiltered initialization have similar or smaller width when comparing PM optimization to DM (FIG. 5A and Table 2). However, the process window alone does not imply accurate computational or physical reconstruction (printing). In fact, the peak mIoU values of DM are significantly smaller than those of PM for unfiltered initialization. With filtered initialization, the process windows of PM are wider than those of DM for all geometries. This outcome is also observed experimentally as a longer time period in which the print can be terminated while retaining high mIoU.

TABLE 2

| | Opt = PM, | Opt = DM | Opt = PM, | Opt = DM |
|---|---|---|---|---|
| Geometry | Init = 0 | Init = 0 | Init = 1 | Init = 1 |
| Octet | 0.179 | 0.281 | 0.220 | 0.186 |
| Thinker | 0.238 | 0.231 | 0.271 | 0.264 |
| Bear | 0.304 | 0.256 | 0.308 | 0.270 |
| Maitreya | 0.194 | 0.286 | 0.225 | 0.218 |

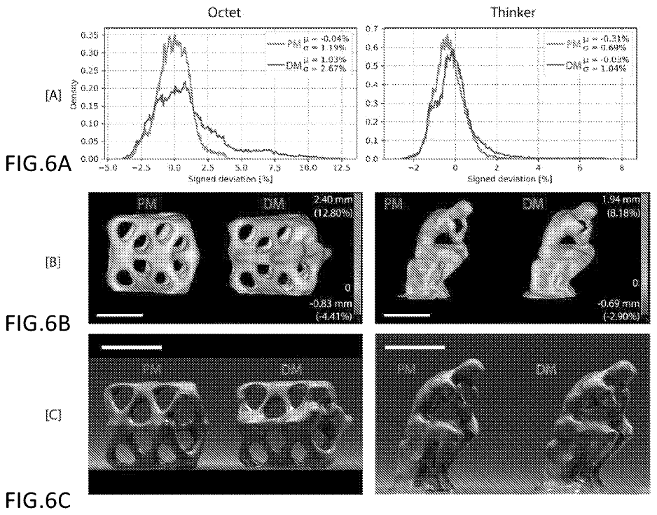

FIGS. 6A-6C show an empirical comparison of printed Octet and Thinker geometries (PM vs. DM), according to an embodiment of the present invention. FIG. 6A shows signed deviation histograms comparing the laser-scanned surface to its respective target surface (PM (red) and DM (blue)), according to an embodiment of the present invention. Deviation is normalized to a percentage of the maximum bounding box dimension of the underlying target geometry. FIG. 6B shows Laser scanned 3D surfaces with signed deviation colomap where red indicates the laser-scanned surface lies outside the target surface and blue indicates the laser-scanned surface lies inside the target surface, according to an embodiment of the present invention. FIG. 6C are photographs of printed and scanned geometries, according to an embodiment of the present invention. Itis noted that printed parts are painted black to reduce reflectivity and improve laser scan ability. Scale bars=10 mm.

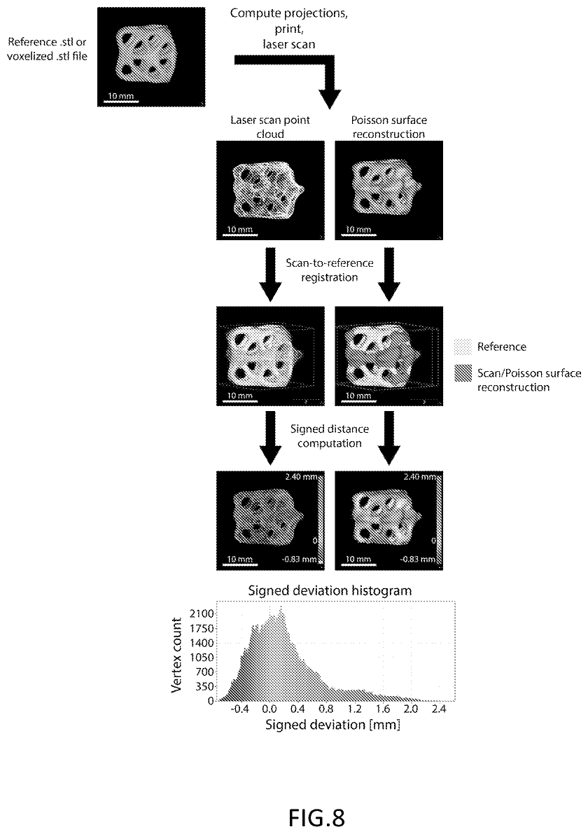

Lastly, we performed laser scanning surface measurement of the printed geometries (FIG. 8 provides the methodology overview). In FIGS. 6A-6C and Table 3, the PM and DM optimized prints of Octet and Thinker are compared directly. In FIG. 6A, the signed deviation data is plotted as a histogram for both PM (red) and DM prints (blue). These Simulated process windows (on relative threshold) for exemplary geometries. See Table 1 for the Opt and Init meanings. The process window is a normalized quantity (shown with a dashed teal line on mIoU curves in FIGS. 5A-5D) and is defined in the text.

FIG. 8 shows a VAM metrology methodology using CloudCompare point cloud software, according to an embodiment of the present invention. The reference (to-be-printed) “.stl” file is used to generate and optimize projections. The CAL 3D print is completed and the post-processed part is laser scanned. The scan point cloud is loaded and its global position is registered to the reference voxelated “.stl” surface. The scan point cloud may be used directly without modification or to create a Poisson surface reconstruction for analysis. Then, the signed deviation between the two surfaces (laser-scanned surface and reference surface) is computed and the data is plotted on a histogram and colormap on the analyzed surface for compact visualization of the print fidelity.

TABLE 3

| Optimizer | | Mean | | Std. Dev. | |
|---|---|---|---|---|---|
| Type | Model | [mm] | [%] | [mm] | [%] |
| Penalty min. | Octet | −0.008 | −0.042 | 0.224 | 1.192 |
| | Thinker | −0.073 | −0.308 | 0.163 | 0.687 |
| | Bear | −0.154 | −0.551 | 0.152 | 0.542 |
| | Maitreya | 0.048 | 0.154 | 0.180 | 0.580 |
| Dose | Octet | 0.193 | 1.031 | 0.501 | 2.669 |
| Matching | Thinker | −0.007 | −0.030 | 0.246 | 1.038 |

Laser scan to voxelated reference geometry: error summary statistics. Laser scans were then compared with the target geometry in order to obtain metrics for fidelity of the reproduction. The empirical scanned surface is colored with the signed deviation from the scanned surface to the voxelated target geometry. Red color indicates the laser-scanned surface lies outside the target surface (too much material) and blue indicates the laser-scanned surface lies inside the target surface (too little material). Additional PM print results of the Bear and Maitreya geometries are included in the Supplementary Materials. PM optimization results in improved conformation to the target geometry compared to the DM approach. In the Octet prints, the PM mean deviation is closer to zero and the standard deviation is significantly smaller. In the Thinker prints, the difference is not as clear. The PM standard deviation is about 30% smaller than DM, whereas the mean is farther from zero signed deviation. However, there are still more apparent local departures from the target geometry in the DM print, most notable are the large positive deviations on the knee and shoulder (FIGS. 6A-6C; also FIGS. 11A-11B and FIGS. 12A-12C). These are indicative of ‘hotspots’ in the background regions (R₂) of the dose distribution, some of which can be observed in the DM dose distribution slices near these features (FIGS. 4A-4E).

PM optimization produces dose distributions with fewer of these ‘hotspots’ and superior dose uniformity which is believed to improve the simultaneity of resin gelation and improve print accuracy. This can be further explored by applying an upper dose constraint in the print region, and appropriately modifying the loss function. Improved uniformity can be observed as a smaller dynamic range of doses within the target contour (R₁) by comparing, for example, the slices of PM in FIG. 3D with those of DM in FIG. 3C. Dose uniformity is compared quantitatively with the coefficient of variation (CV) of the dose in the target region R₁, where CV is defined as the standard deviation of the dose in R₁ divided by the mean of the dose in R₁. The CV for PM Octet and DM Octet are 0.069 and 0.096, respectively, and the CV for PM Thinker and DM Thinker are 0.066 and 0.071, respectively. As the dose uniformity increases (equivalently, CV decreases), the transitional time over which crosslinking occurs shrinks. This effectively reduces resolution deterioration due to “overcuring” and part sedimentation, resulting in more accurate fabrication.

We note that optical metrology (from FIG. 6A) suggests that the deviation is not on par with what is theoretically suggested. This could be due to a number of factors, including imperfections in the forward model (optical: diffraction, attenuation, chemical: photoactive and inhibitor species diffusion) as well as the finite process window. Nevertheless, it is evident that the objects printed with PM-optimized projections exhibit improved conformation to the target compared to objects printed with DM-optimized projections. We attribute the improved performance to the steeper onset of gelation (as seen in FIGS. 5A and 5B), higher maximum mIoU, more uniform dose distribution within the target, as well as typically flatter mIoU peak and wider process window produced by the PM approach.

Starting from these promising results, there are several future directions this work could take, including incorporating steep exponential light intensity decay (Beer-Lambert law) due to resin attenuation co-efficient and opaque occlusions as well as optical diffraction in the forward model. The latter may lead to a better match with physical implementations of the technique, as well as an understanding of its fundamental physical limitations.

We have developed a new projection optimization approach in the emerging field of tomographic volumetric additive manufacturing. A principled optimization approach was used to minimize dose violation penalties for high fidelity printing. Optimal projection intensities were obtained by using a quasi-Newton L-BFGS-B optimizer on the specified loss function. The projector intensities and 3D dose distribution were evaluated computationally and validated experimentally with real printing. The PM optimization approach was shown to per-form better than the DM optimization in nearly all computational metrics. As measured by 3D optical metrology, objects printed with PM-optimized projections exhibit improved conformation to the target geometry in terms of the standard deviation of the signed deviation between measured and target reference surfaces.

Materials and methods: File formats and data: The ‘Octet’, ‘Thinker’, ‘Maitreya’ and ‘Bear’ geometries were obtained through CC non-commercial licenses from online stereolithography file repositories. The “.stl” files were converted to voxel arrays using the implementation in https://github.com/cpederkoff/stl-to-voxel. All file formats, data and results (stored as “.npy” arrays) are available on request.

Implementation: The optimization algorithm and all ancillary functions were implemented in python3 using the packages NumPy, ImageIO, OS, SciPy, Skimage and MatplotLib. The radon, iradon and rescale functions from Skimage were used, whereas the Optimize module and resample function from SciPy were used. The optimizer used was L-BFGS-B, a built-in method of the scipy.optimize.minimize function. The hyperparameters used for L-BFGS-B were consistent for both the penalty minimization and dose matching approaches: ‘maxiter’: 40, ‘ftol’: 1e-12, ‘maxcor’: 10, ‘maxls’: 30. All other hyperparameters used default values. The analytical loss and loss gradient functions were implemented in python3. The scipy.ndimage.morphology module was used to erode and dilate the as-imported geometries in order to define the target, buffer and background regions for the optimization algorithm. A morphological structuring element was defined for each 2D slice of the geometry. The structuring element was a square kernel of side three pixels, leading to an approximate buffer region width of two pixels each 2D slice. MatplotLib was used for all plotting. All functions were implemented in a jupyter notebook that is available on request. The voxel geometries were converted to .stl files using marching cubes and were used in laser scanning comparisons.

Materials: The resin formulation used for the printing experiments consists of urethane dimethacrylate IPDI (Esstech X-851-1066) prepolymer with refractive index of 1.4938 and 0.25 M2-Methyl-4-(methylthio)-2-morpholinopropiophenone (Sigma-Aldrich, CAS: 71868 Oct. 5) photoinitiator. The absorption coefficient of the resin was measured with UV-VIS spectroscopy. It had low absorptivity of 0.05 cm⁻¹ at the center wavelength of the illumination source (409 nm) (FIG. 7). Since no diluents were added, the resin had a dynamic viscosity of 100,000 cP according to the manufacturer's specifications. Prints were carried out in 20 mL scintillation vials. Prints were terminated by visual feedback provided by the shadowgraphy system shown in FIG. 2A. More sophisticated methods such as Schlieren tomographic reconstruction may also be used as quantitative print feedback. After print completion, excess resin was drained and parts were rinsed twice for 30 s with 50° C. acetone and post-cured for 15 min in a 405 nm UV cure chamber (Formlabs Cure).

Hardware and optical setup: A LC4KA-EVM projector (Keynote Photonics) with DLP660TE digital micromirror device and 405 nm LED source was used for light exposure. The projected light beam was collimated and directed into an index matching box (Edmund Optics 45-371). After collimation, the projected pixel size and pixel resolution at the midplane of the print container was 31.4×31.4 μm and 2716×1528, respectively. The intensity for a pixel with maximum bit value 255 was 10.5 mW cm⁻². The print container was mounted on a rotation stage (Thorlabs K10CR1) with rotation speed 24° s⁻¹ and submerged in glycerol, used as the index matching fluid to reduce refraction at the cylindrical container's surface during printing Perpendicular to the projected light path, a shadowgraphy imaging system was constructed. Light from a multimode optical fiber was collimated and directed through the index matching box and resin container (Thorlabs AC508-180-A). Two lenses opposite the fiber (Thorlabs AC508-080-A and Thorlabs AC254-030-A), focus the light onto an imaging sensor (body of Panasonic GH4). The camera captures the resulting shadowgram of the print volume inside the resin container to monitor the formation of the object.

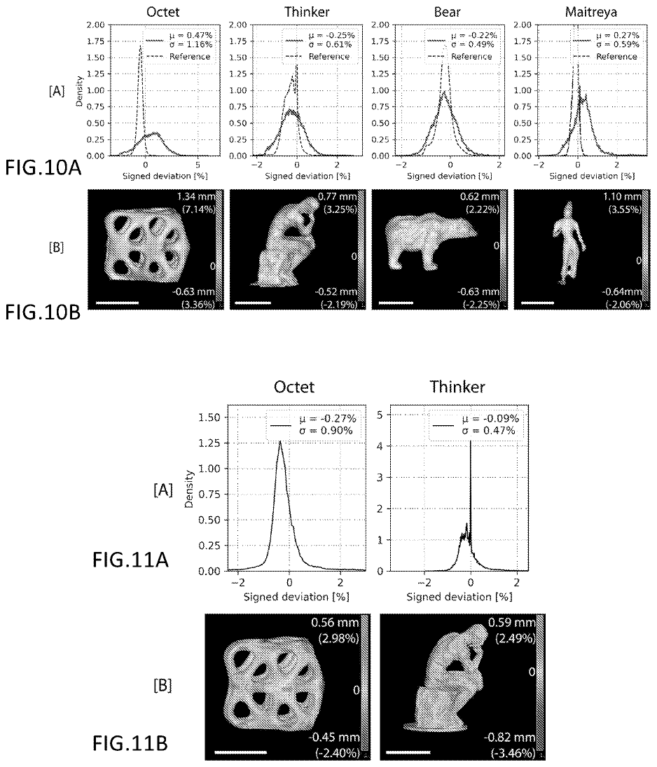

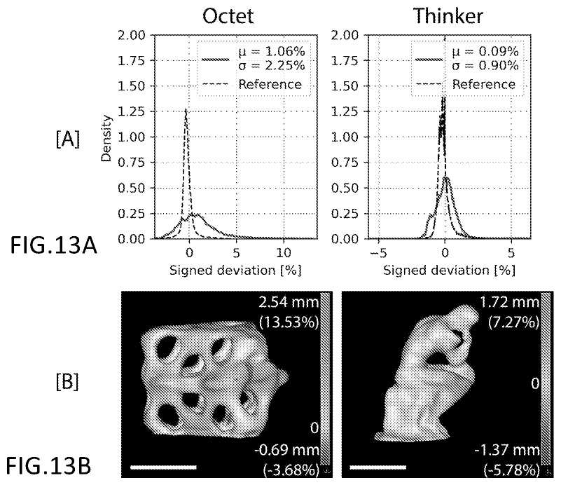

Laser scanning measurement: After post-processing, the printed objects were coated with a matte black paint to make the surface opaque and reduce reflectivity. The parts were then scanned with a Romer Absolute arm RA-7525 SI (Hexagon Metrology) with 63 μm scanning accuracy. The scan point clouds were imported into CloudCompare and the following signed deviation comparisons were calculated (after appropriate registration and alignment; see FIG. 8 for process overview): (i) laser scan to voxel target geometry (FIGS. 6A-6C, FIGS. 9A-9C, and FIGS. 12A-12C), (ii) best threshold dose isosurface to voxel target geometry (FIGS. 5A-5D, and FIGS. aaA-11B), and (iii) laser scan to best threshold dose isosurface (FIGS. 10A-10B and 13A-13B).

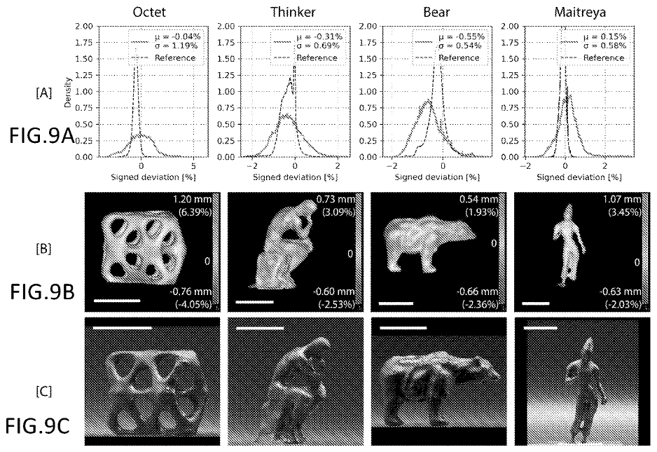

FIGS. 9A-9C show Laser scanning measurement of all PM-optimized geometries compared to reference geometries, according to an embodiment of the present invention. FIG. 9A shows a signed deviation histograms (red) comparing laser scan surface to target geometry, normalized to a percentage of the maximum bounding box dimension of the underlying target geometry, according to an embodiment of the present invention. The reference histogram (dashed black) shows the comparison of the simulated prints at the optimal threshold for peak mIoU to the target geometry (FIG. 5C). FIG. 9B shows a Laser-scanned 3D surface with signed deviation colormap where red indicates laser-scanned surface lies outside the target surface and blue indicates the laser-scanned surface lies inside the target surface, according to an embodiment of the present invention. FIG. 9C shows photographs of printed and scanned geometries, according to an embodiment of the present invention. Itis noted that printed parts are painted black to reduce reflectivity and improve laser scannability. Scale bars=10 mm.

FIGS. 10A-10B show Laser scanning measurement of all PM-optimized geometries compared to best simulated geometries using filtered initialization, according to an embodiment of the present invention. FIG. 10A shows a signed deviation histograms (blue) comparing laser scan surface to the PM best simulated surface geometry, normalized to a percentage of the maximum bounding box dimension of the underlying target geometry, according to an embodiment of the present invention. The reference histogram (dashed black) shows the comparison of the simulated prints at the optimal threshold for peak mIoU to the target geometry (FIG. 5C). FIG. 10B shows a Laser-scanned 3D surface with signed deviation colormap where red indicates the laser-scanned surface lies outside the simulated surface and blue indicates the laser-scanned surface lies inside the simulated surface, according to an embodiment of the present invention. Scale bars=10 mm.

FIGS. 13A-13B shows Laser scanning measurement of DM-optimized geometries compared to best simulated geometries using filtered initialization, according to an embodiment of the present invention. FIG. 13A shows signed deviation histograms (blue) comparing laser scan surface to the DM best simulated surface geometry, normalized to a percentage of the maximum bounding box dimension of the underlying target geometry, according to an embodiment of the present invention. The reference histogram (dashed black) shows the comparison of the simulated prints at the optimal threshold for peak mIoU to the target geometry (FIG. 5C). FIG. 13B shows a Laser-scanned 3D surface with signed deviation colormap where red indicates the laser-scanned surface lies outside the simulated surface and blue indicates the laser-scanned surface lies inside the simulated surface, according to an embodiment of the present invention. Scale bars=10 mm.

High Fidelity Volumetric Additive Manufacturing: Resin chemistry and photopolymerization: With the choice of resin chemistry in this work, the majority of the light dose is accumulated in the induction period before resin gelation. Note that gelation occurs when the prepolymer's density begins to increase and the storage modulus of the medium exceeds its loss modulus. During the oxygen induction period, the optical dose generates free radicals that primarily react with molecular oxygen dissolved in the prepolymer. Only after sufficient ( ) depletion can the photopolymerization begin. For low to moderate intensity (as in this case), the number of free radicals generated during the induction period is linearly proportional to dose, where dose is the product of intensity and exposure time. In the current work, we use a constant rotation rate and do not attempt to change the illumination intensity across successive rotations of the print vial. Thus, we may express the dose distribution as a product of the number of rotations N, and the dose deposited in a single rotation. There may potentially be some benefit to modifying the exposure recipe over the course of successive rotations in order to accommodate non-linearities and the diffusion of chemical species. The non-linearities primarily arise from the photopolymerization process (as opposed to the induction phase). We have proceeded with the constant-rotation-rate method in this work since the induction phase consumes a large fraction (80-90%) of the dose for this chemistry.

We further assume that the high viscosity of the resin used in experimentation significantly limits free radical and O₂ diffusion. Diffusivities of O₂ on the order of 10⁻⁴-10⁻⁶ cm²/s in monomers and other organic liquids with viscosities on the order of 1-50 cP have been reported [23, 24, 25]. The diffusion rate for small molecules in liquids of high molecular weight is proportional to the −⅔ power of the liquid's viscosity which means that the high viscosity monomer used in this work (100,000 cP; see Section 6.3) has O₂ diffusivity on the order of 10⁻⁸ cm²/s. The characteristic diffusion length over a 500 s print time (similar to prints in this work) is 10 μm, which is smaller than the expected minimum feature size (˜500 μm) and also smaller than what is resolvable with the 3D optical metrology. Therefore, we have neglected the effect of oxygen diffusion in the forward model.

Discretization: DLP projectors have a fixed space-bandwidth product (etendue), as well as a temporal frame rate at which the video can be projected. This discretization needs to be accounted for in the forward model and the projection calculation. We consider how the spatial resolution, temporal frame rate and angular rotation rate of the vial determine the discretization of the projection space intensity from g(ρ, θ, z) and the resulting 3D dose distribution f(r, z). We will represent the discretization of the continuous intensity g as G_{i,j,k} over a specific basis of the projection space (ρ, θ, z). The basis will be described in terms of the natural discretization of the projection space. This discretization will then inform the choice of sampling used in representing the inverse problem, so long as computational resources are not a constraint. The finite frame rate induces a discretization in the angular domain θ.

If the maximum possible projector frame rate is fₚ frames per second, the angular resolution is determined by the angle rotated during a single frame: δθ=Ω/fₚ. It is possible to obtain improved angular resolution by rotating slowly and reducing the total number of rotations so as to maintain consistent total dosage. However, the fast angular rotation rate case provided sufficient angular resolution based on spatial frequency sampling arguments described in Kelly et al. In order to describe spatial discretization, we consider the image intensity distribution of a single projector pixel prior to resin attenuation. Consider a particular projector pixel, indexed by radial and height indices of the projector. When this is imaged into the resin volume, it results in a spatially continuous function ψ₀(ρ, z) where ρ is the radius variable along the vector θ\hat{ } corresponding to the instantaneous angle θ of the projector. If we define this pixel function ψ₀ as centered at the origin of the coordinate system along height and radius, the other pixels produce a response given by ψ₀((ρ−ρᵢ, z−zₖ). ρᵢ and zₖ lie on a Cartesian grid along radius and height. Note that the height direction is parallel to the axis of rotation of the print medium. The intensity distribution resulting from a single pixel ψ₀ is concentrated around ρ=0 due to finite pixel size, and is here defined for unity projector pixel intensity. Together with the spatial pixel resolution, the finite angular resolution imposes a projection space voxel given by: φ₀(ρ, θ, z)=ψ₀(ρ, z)×b_{δθ}(θ) where b_{δθ}(θ) is a boxcar function in the angular domain (centered at 0 and with support of δθ). We can then express the continuous projection intensity function as a linear combination of the individual voxel basis functions, weighted by discrete projector intensities:

$$f ( ρ , θ , z ) = {\sum }_{i , j , k} {G}_{i , j , k} {ϕ}_{i , j , k} ( ρ , θ , z ) where {ϕ}_{i , j , k} ( ρ , θ , z ) = {ϕ}_{0} ( ρ - {ρ}_{i ,} θ - {θ}_{j} , z - {z}_{k} ) . \qquad ( 11 )$$

The goal of the optimization is to determine a feasible solution for the projector intensities G_{i,j,k} in energy flux units, subject to the physical constraints:

$$0 \leq {G}_{i , j , k} \leq {G}_{max} \qquad ( 12 )$$

where Gₘₐₓ is the maximum power of a projector pixel in W/cm². Constraints in print space (r, z) are described in Section 3 below. In the calculation, we will also impose a target region voxelization, where the target geometry is treated in terms of discrete voxels. The target geometry voxels should ideally have dimensions smaller than or equal to those imposed by the projection space voxel. This is in order to sample the real space dose distribution in a sufficiently dense manner while calculating the loss function and its gradient. However, it is possible that this is computationally infeasible, particularly given the large number of pixels available in modem projectors. We decided to sample the projector intensity at a coarse pixel size, 2-4×larger than the available pixel size. This was done in order to allow the calculation to be computationally tractable on a personal laptop. With additional computational resources, it is likely that the full resolution of the projector can be used. In order to map the coarse projection intensities to the pixel, a conventional upsampling method was used. Due to the rather coarse representation of the problem, it is acceptable here to consider the ray optics limit in our forward model description as opposed to a wave-optics-based Abbe image formation model. The ray optics model allows us to use the exponential Radon transform in our forward model description and accelerates the optimization procedure. In our comparison metrics, we have always compared the print geometries with the coarser representation that was used in order to initialize the problem.

We also note some additional assumptions related to the aforementioned projection voxel basis functions. These assumptions help to simplify the calculation without affecting the accuracy of the forward model significantly under the chosen physical settings of the problem. Firstly, we note that the basis function do (p, z) may be close to a simple boxcar function with finite support, but it will depend on the shape of the projector pixel, the color tiling scheme used by the DLP manufacturer as well as details of the optical system and resin optics, particularly the imaging modulation transfer function of the projector into the resin vial. A more physically accurate picture of the dose basis function is a ‘pixel spread function’ resulting from the imaging of a DLP pixel into the exposure medium. This concern is nullified by our representation of the problem at a computational pixel size that is significantly coarser than permitted by hardware. Additionally, we also note that the diffraction tomography framework is more suitable for fully incorporating the scalar wave theory physics of this problem when it is treated close to the hardware pixel size. However, the current ray optics picture allows us to neglect the angular dependence of the ‘pixel spread function’ in the resin volume and treat it as an integral projection of a boxcar DLP projector pixel. Lastly, we have also assumed a perfect step-like transition in time as the frame changes, which allows the angular response to be approximated as a boxcar function b_{δθ}(θ). A more precise approach would be to explicitly consider the rise and fall times of the projector pixel values and incorporate this in the angular integration formula of 2, assuming a constant angular rotation rate. While these concerns regarding the discretization and treatment of the physics model are valid, they do allow a more simplified computational description. For instance, the simplification permits the use of fast-Fourier-transform-based packages for the Radon transform and inverse Radon transform in solving the inverse problem iteratively, which is especially important given the iterative approach. A fast Laplace-transform-based approach is also possible for the exponential Radon transform.

Connection to heuristic gradient descent approach: We observe that the PM method generalizes the heuristic finite difference approach proposed by Kelly et al. Here we argue how the PM method is a superset of techniques from which the prior approach can be derived. In the previous heuristic method, the notion was that the projection space update should be calculated by using a Radon transformation (integral projection) of the violating volumes at each iteration. The violating volumes were calculated for three perturbed gelation thresholds and the Radon transform was calculated on the mean of these violations. This led to a projection space update vector, which was used to change the projector weights at that iteration of optimization. If we denote the loss gradient in projection space as ∂ [symbol] /∂g, this Radon transform approach can be formalized by expressing the updating gradient as:

$$\frac{\partial ℒ}{\partial g} ( ρ , θ , 𝓏 ) ∼ - {T}_{- α} [ {I}_{v i o l} ( r , 𝓏 ) ] \qquad ( 13 )$$

where Iᵥᵢₒₗ(r, z) is an indicator function over the violating volumes in the print space and T_{-α} denotes the exponential Radon transform (˜indicates proportionality). The indicator function is 1 where we have undesirable excess dose and −1 where it is lower than desired (zero elsewhere). Now, performing an inner product in projection space [symbol] using pixel basis functions φ_{i,j,k}(ρ, θ, z) yields the loss gradient for each pixel (substituting from equation S3):

$$\frac{\partial }{\partial {G}_{i , j , 𝔨}} ℒ [ t ] = {〈 {ϕ}_{i , j , k} \vert \frac{\partial ℒ}{\partial g} ( ρ , θ , 𝓏 ) 〉}_{𝒫} ∼ - 〈 {ϕ}_{i , j , k} \vert {T}_{- α} \vert {I}_{v i o l} ( r , 𝓏 ) 〉 𝒫 \qquad ( 14 )$$

where <|>ρ bra-ket notation for the inner product formed by integration in projection space. However, by definition of the Hermitian adjoint, we have the following identity:

$${〈 {ϕ}_{i , j , k} \vert {T}_{- α} \vert {I}_{v i o l} ( r , 𝓏 ) 〉}_{𝒫} = 〈 {I}_{v i o l} ( r , 𝓏 ) 〉 \vert {T}_{- α}^{*} \vert {ϕ}_{i , j , k} \qquad ( 15 )$$

where <|> [symbol] denotes the inner product formed by integration over real space (r, z) and T*_{-α} denotes the exponential backprojection operation. It is easy to then confirm that the right hand side of equation S5 is proportional to the right hand side of equation 6:

$$〈 {I}_{v i o l} ( r , 𝓏 ) \vert {T}_{- α}^{*} \vert {ϕ}_{i , j , k} = {\int }_{∼ {V}_{1} [ t ]} ( {T}_{- α}^{*} [ {ϕ}_{i , j , k} ] ( r ) ) d r - {\int }_{∼ {V}_{2} [ t ]} ( {T}_{- α}^{*} [ {ϕ}_{i , j , k} ] ( r ) ) d r \qquad ( 16 )$$

Since the loss gradients are proportional, the heuristic method in the previous demonstration by Kelly et al. formalizes to the L₁ penalty minimization approach proposed here. However, we note that the previous optimization method was a heuristic: the idea of using the Radon transform of the violating volumes as the projection space update was based on the intuition that convergence would be obtained when there were no more violating volumes. Instead, expressing the problem in terms of an analytical loss function has very important practical as well as conceptual advantages. In terms of computation, the use of an analytical loss function, and its analytical gradient is well known to lead to much better convergence of mathematical optimization approaches. In fact, the use of the L-BFGS-B algorithm (discussed in Section 3.3) requires the use of an analytical gradient: the update step is very different from simple gradient descent. Secondly, expressing as a loss function allows us to explore precise dose constraints, as well as other loss functions. For instance, an L₂ loss, or loss function incorporating other dose constraints, will not be mathematically equivalent to the earlier approach.

Computed axial lithography (CAL) is a recently developed form of resin-based volumetric additive manufacturing (AM) inspired by the tomographic principles of computed axial tomography and intensity modulated radiation therapy. In CAL, 2D images are projected through a rotating cylindrical volume of photosensitive material such that the cumulative 3D energy dose is sufficient to polymerize the design geometry. Because CAL is a layerless AM method, it is possible to print without supporting structures, to produce smooth surface finishes and to print in less than 10 minutes. In general, the photosensitive material has a high viscosity to limit sedimentation of the printed part during exposure and adequate transmission at the patterning wavelength. Currently, design of projections does not account for variability of photochemical responses of different resins. Interestingly, rotation during exposure also enables in situ tomographic 3D imaging of part formation which could provide material conversion feedback. Sharpe et al. have developed a 3D imaging technique called optical projection tomography (OPT), used to probe 3D gene expression in biological samples, which bridges the gap between relatively low-resolution, large-scale methods like magnetic resonance imaging and micro-scale confocal fluorescence microscopy. However, the moderately high numerical aperture (NA) needed to resolve individual cells limits the depth of focus and samples must be in the range of 1-10 mm across. Improvements such as focal scanning via piezoelectric stages or electrically tunable lenses may be used to increase the im-ageable volume but may increase the projection acquisition time. Additionally, this method is only designed to detect the distribution of cells with fluorescent markers.

Tomographic imaging has previously been applied to volumetric AM to estimate local polymerization time and update dose prescription. Loterie et al. visualized photopolymerization with monochrome transmission imaging. Their system was assembled in a “focused” shadowgraphy configuration in which an expanded and collimated red laser was used as the light source. Shadowgraphy systems image the second spatial derivative of the refractive index (RI) or the gradient of the RI gradient. The local solidification time is determined by identifying the earliest time at which the corresponding volume element (voxel) appears to be darkened by more than an empirically-determined intensity threshold when observed from all angular projections. The local solidification time is then used to modulate the dose prescription to achieve simultaneous polymerization throughout the part. This technique only provides binary polymerization classification; thus information about the density and RI of the inhomogeneous region is inaccessible. By the design of this algorithm, solidification is not classified until a voxel appears to be darkened at all angles, leading to time inaccuracies and miscounting of voxels that are transparent at some views.

Schlieren imaging has long been an effective method for both qualitative assessment and quantitative analysis of fluid properties (i.e., pressure, density, and temperature fields) in a variety of scientific fields. Several demonstrations have shown that Schlieren images processed with tomographic reconstruction techniques can produce a 3D map of RI field and subsequently pressure, density, etc. In a real system, however, a source with finite extent is partially blocked by an amount that is proportional to the source image displacement relative to the knife edge. For a rectangular slit source, the relative intensity variation due to this displacement can be given. A continuous measurement of RI by tomographic Schlieren imaging would provide several benefits. It allows the progression of the polymerization process to be spatially and temporally tracked. Compared to binary threshold-crossing detection, continuous measurement directly quantifies the local error in degree of conversion, which is useful for real-time projection correction. Additionally, the time derivative of conversion can be estimated at any location. Finally, the high sensitivity of the Schlieren imaging also enables detection of undesirable background conversion of the resin precursor surrounding the target geometry.

In this paper, a color Schlieren imaging system is constructed to enable quantitative process feedback in CAL. First, an introduction to the mathematics of Schlieren imaging based on geometric optics is given and the theory of filtered backprojection for tomographic reconstruction from ray-deflection projections is presented. Then, the construction of an astigmatism-corrected Schlieren imaging system and color filter that encodes transverse RI gradient are de-tailed. Finally, the algorithm for computational reconstruction is described and accuracies of estimated print geometries are evaluated by dimensional comparison with printed components.

Schlieren Theory: Conventional Schlieren imaging, as introduced by Töpler [Töpler 1867], is performed by introducing a knife-edge cutoff in the Fourier plane as a frequency cutoff in the imaging device (which is at the conjugate plane of the source). In the resultant 2D image, this filtering action introduces intensity variations which correspond to the RI inhomogeneities in the test area.

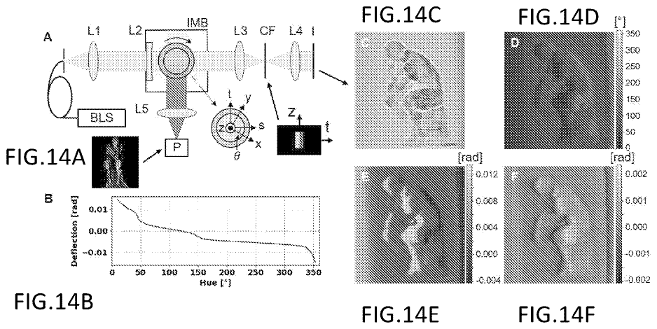

The following ray deflection analysis is derived from geometric ray optics with paraxial approximations and most relevant equations are reproduced from Settles and Agrawal et al. In general, when an undisturbed ray traveling along the s-axis (FIG. 14A) encounters a region with RI variation in the t-direction it is deflect according to:

$$ε = \frac{1}{{n}_{0}} \int \frac{\partial n ( t , s , z )}{\partial t} \partial s \qquad ( 17 )$$

where ε is the angular deflection about the z-axis relative to the positives-axis, n₀ is the RI of the surrounding, and ∂n/∂t is the gradient of the RI in the t-direction within the t-s plane. Assuming a small deflection, where ε˜tan ε, the spatial displacement in the Fourier plane along the t-axis can be expressed as

$$d = {f}_{ε} \qquad ( 18 )$$

where f is the focal length of the Schlieren lens in a dual-field-lens arrangement.

The intensity distribution in the Fourier plane replicates that at the light source plane because these are conjugate planes. For an ideal point light source, displacement towards or away from the knife edge in the Fourier plane results in either complete cutoff or passaged of deflected rays. In a real system, however, a source with finite extent is partially blocked by an amount that is proportional to the source image displacement relative to the knife edge. For a rectangular slit source, the relative intensity variation due to this displacement can be given as

$$\frac{Δ I}{I} ∼ \frac{f}{a} ε \qquad ( 19 )$$

where a is the width of the unblocked portion of the source rectangle. Thus, the sensitivity of the system for a given RI inhomogeneity is dependent on both the focal length of the second field lens and the degree of cutoff of the source image. In place of a knife-edge, a neutral-density graded filter may be used for increased measurement range i.e. the degree of deflection or magnitude of the gradient of the RI, at the cost of reduced sensitivity. Similarly, a graded color filter may be used.

Tomographic reconstruction is the inverse problem of estimating a function from a set of angularly separated projections each containing line integrals through the function domain. In this case, the function to be reconstructed is the RI field and the line integrals take the form of Equation 4. The ray deflection angles are the projected variables to be observed.

In order to reconstruct the 3D field, the problem is reduced to reconstruction of 2D slices that can be assembled to approximate the 3D field. In this analysis, normals of these slices are parallel to the rotation axis (z axis) of the print volume. For a projection angle θ, the x-y coordinate system (fixed relative to the vial) is transformed to the t-s coordinate system (fixed relative to the optical system). For a given z-slice, at projection angle θ, the transverse angular deflection (angle relative to the s-axis), ε_{θ}, then becomes

$${ε}_{∅} ( t ) = {\int }_{- ∞}^{∞} \frac{\partial \hat{n} ( t , s )}{\partial t} \partial s \qquad ( 20 )$$

where

$$\hat{n} = \frac{n - {n}_{0}}{{n}_{0}}$$

is the normalized RI change from the background RI, n₀ (n₀ is the RI of completely uncured resin precursor material), and ∂\hat{n}/∂t is the gradient of the normalized RI in the transverse t-axis. Assuming negligible attenuation and a straight optical path, the order of differentiation and integration may be changed:

$${ε}_{∅} ( t ) = \frac{\partial }{\partial t} {\int }_{- ∞}^{∞} \hat{n} ( t , s ) \partial s . \qquad ( 21 )$$

If the ordinary line integral projection is

$${p}_{∅} ( t ) = {\int }_{- ∞}^{∞} \hat{n} ( t , s ) \partial s \qquad ( 22 )$$

then the Fourier transform of Equation 5 can be written as

$${E}_{∅} ( {f}_{t} ) = i 2 π {f}_{t} {P}_{θ} ( {f}_{t} ) . \qquad ( 23 )$$

When absorption is negligible, the RI field for the z-slice can be reconstructed from the Fourier transform of a set of ordinary projections, P_{θ}(fₜ), where θ∈[0, π]:

$$\hat{n} ( x , y ) = {\int }_{0}^{π} [ {\int }_{- ∞}^{∞} {P}_{θ} ( {f}_{t} ) exp ( i 2 π {f}_{t} t \vert {f}_{t} \vert {df}_{t} ] d θ \qquad ( 24 )$$

where |fₜ| represents the frequency response of the filter applied to the projections such that the sum of the back projections gives an estimate of \hat{n}(x, y) which approaches an exact reconstruction as sampling density is increased. Rearranging and substituting from Equation 23 and t=−x sin θ+y cos θ gives

$$\hat{n} ( x , y ) = - \frac{i}{2 π} {\int }_{0}^{π} \{ {\int }_{- ∞}^{∞} {P}_{θ} ( {f}_{t} ) exp ( i 2 π {f}_{t} t \vert {f}_{t} \vert {df}_{t} ] \} d θ \qquad ( 25 )$$

where sgn(fₜ=|fₜ|fₜ is the sign function. The frequency response of the filter modified for reconstruction of ray deflection projections is −i sgn(fₜ)/2π.

Experimental Setup, Color Filtering: As an alternative to the knife edge of ordinary Schlieren imaging, a graded color filter can be used to encode the locations of rays in the Fourier plane into color instead of intensity. In this work, a 5 mm×20 mm linear-hue color filter is constructed by commercial photographic recording (Slides from Digital, Oakland, CA), where hue (of the hue-saturation-intensity (HSI) color space) varies from 0° to 360° linearly end-to-end, as shown in FIG. 14A. With this filter, rays' ε_{θ}(t) deflections result in changes of hue observed in the Schlieren image. Together with a color image sensor, the shifts in color can be mapped back to ray deflections for tomographic reconstruction of the RI field.

FIG. 14A is a schematic diagram of an optical setup, according to an embodiment of the present invention. The Schlieren imaging system is positioned perpendicular to the CAL patterning light. A fiber-coupled broadband tungsten-halogen source (Thor-labs SLS201) is shaped to a slit source with metal blades at the output and used as the white light source. Identical 180 mm focal length (FL) achromatic doublet lenses (Thorlabs AC508-180-A-ML) are used as the Schlieren field lenses (L1 and L3). L3 is positioned one focal length away from the center of the vial. An acrylic box contains mineral oil (n≈1.47) for approximate index matching the vial containing urethane dimethacrylate IPDI monomer (Esstech #X-851-1066) (n=1.4938) with 0.25 M concentration of Irgacure 907 photoinitiator. A cylindrical planoconcave lens (Thorlabs LK1900L1) is used to compensate further for astigmatism introduced by remaining index mismatch (L2). A 30 mm FL achromatic doublet lens is used as the focusing lens (L4) (Thorlabs AC254-030-A-ML). The camera used is a Panasonic GH4 body (without lens) set in 24 fps and 3840×2160 pixel video capture mode. FIG. 14B is a plot of angular deflection versus the hue, according to an embodiment of the present invention. FIGS. 14C-14F show results of the tomographic reconstruction procedure after all video frames are captured, according to an embodiment of the present invention.

Compared with traditional intensity-based ray deflection representations, adoption of an intensity-decoupled color representation could potentially make the index imaging system more robust against changes in scattering and achromatic absorbance. Moreover, intensity information carried by light rays is not fully discarded in the color filtering process so the preserved achromatic absorbance information could be further extracted for other purposes (e.g., tomographic absorbance reconstruction). As a side benefit, the color-coding scheme also allows more sophisticated filters to be developed in the future to simultaneously encode vertical and horizontal ray deflections.

The half plane occupied by the knife edge in conventional Schlieren imaging represents the half plane of spatial frequencies and corresponding phase front directions removed from the Fourier plane. The gradient direction of the color filter resembles that of the knife edge counterpart, selecting the ray deflection direction to be observed. In FIG. 14A, this normal direction is along/and hence only ray deflections projected onto the t direction are observed. Any ray deflections that are not directly aligned with t will be observed with a lower sensitivity, following vector projection principles. The hue gradient on the filter determines the sensitivity of the deflection measurement. The lateral dimension of the color filter is chosen such that the maximum ray displacement caused by sample inhomogeneities is contained in the transmissive region.

Before the printing experiment is run, we first calibrate the deflection-hue transformation. Itis typical in Schlieren systems to calibrate the intensity or hue transformation with a standardized target such as a weak lens of known focal length and index of refraction. We follow this technique by placing a planoconvex cylindrical lens (Thorlabs LJ1874L1) near the center of the field-of-view and capturing an image of the color variation as a function transverse distance from the center of the lens. The deflection-hue calibration curve is generated by mapping the theoretical ray deflection calculated with Snell's law to the hue channel.

Computational Reconstruction: The tomographic reconstruction procedure (Algorithm 1) begins after all video frames are captured. The expected resolution is 50 pixels/mm on the image plane. All video is captured at 24 fps. Depending on the rotation speed (24° s or 12° s), there are 360 or 720 frames per rotation, and there are several rotations per fabricated component. A 15×15 pixel averaging filter was applied to raw captured frames to reduce their effect in the reconstructions. Each frame (projection) is converted to HSI with the OpenCV library, and the hue channel is extracted and transformed to ray deflection with the calibration curve obtained during setup. Then, if the frame is captured in the first rotation, it is saved and used later for background deflection subtraction. After this, the filter in Equation 9 (−i sgn(fₜ)/2π) is applied in the frequency space. The results of these steps are shown for an example frame in FIGS. 14C-14F. To obtain a series of time-sampled sinograms (projection set) for reconstructions, we evaluated three different time-segmentation approaches, which are described in the following paragraphs. Finally, each set of projections in the θ range [0, 2π) corresponding to a time point is backprojected in 3D with Astra Toolbox. Projection data on [0, 2π) is used instead of [0, π) because of asymmetric hue changes induced by imperfect rotation axis concentricity of the vial fixturing. The result is saved as a 3D array in which each element contains the relative RI field change.

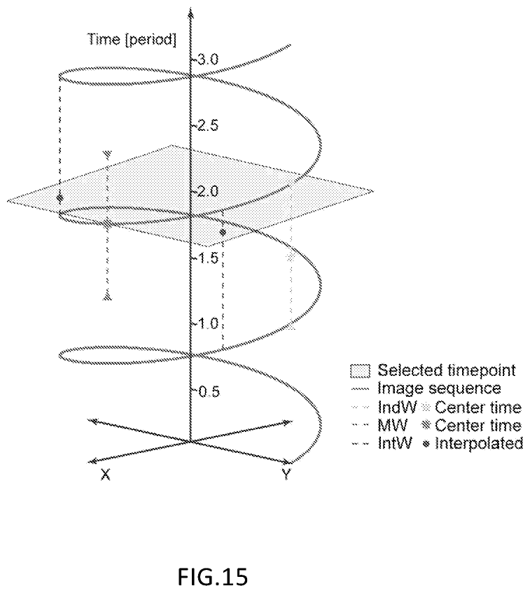

Time-segmentation: The projection images are taken at increasing time points and azimuthal angles, creating an imaging sequence that is helical in time-angle space, as shown in FIG. 15. For complete reconstruction, images have to be grouped into sets of 0-360° projections. However, the polymerization state of the material evolves during any given revolution, so the method of grouping the projection data prior to reconstruction may affect temporal resolution and reconstruction quality. We therefore implemented and compared three possible time-segmentation methods with increasing time-correction capability.

Algorithm 1 Algorithm for reconstructing
RI evolution with time- segmentation

Input: video file
Output: time series of 3D RI arrays
1: foreach frame in video
3: optional: frame = blur(frame)
2: H = rgbtohsi(frame)
3: ε_{θ} (t, z) = interp(H , calibcurve)
4: if frame in 1 st rotation, then bgd_{θ} = ε_{θ} (t, z)
5: else
6: ε_{θ} (t, z) = ε_{θ} (t, z) − bgd_{θ}
7: filter(ε_{θ} (t, z))
8: Compute time points and indices of reconstruction frames with
chosen time-segmentation approach
9: do reconstructions

The first, naïve, approach to reconstruct the evolving RI field is to consider each 0-360° set of projections as an independent window (IndW) of data. Because projections are not acquired simultaneously, each independent reconstruction actually represents the \hat{n} field spanning the time of one rotation period centered in the middle of that period. As rotation rate and period are inversely proportional, the time resolution of the approach increases with in-creasing rotational velocity ω. However, clearly this method cannot resolve events occurring on a time scale shorter than the window timespan and if higher temporal resolution is desired the frame rate of the imaging sensor must increase with ω in order to maintain high angular sampling rate f_{θ}.

As an extension of the IndW approach, the moving window (MW) approach selects the subset of projection data for reconstruction at more finely resolved time. One reconstruction can be performed per frame instead of per rotation. Each forward time step is accomplished by adding the next acquired frame in the image sequence to the MW, removing the oldest frame in the MW (f_{θ} remains constant), and reordering projections to maintain constant reconstruction orientation. The midpoint in time of the MW (FIG. 15) is taken to be the timepoint of reconstruction. Consequently, there is a minimum delay of one half the window time span. With this technique, time resolution is similarly limited by the rotation period (window size) and the frame rate of the imaging sensor.

FIG. 15 shows a visual representation of Schlieren-time segmentation geometry, according to an embodiment of the present invention. Time is exchanged with the z-axis and a single projection frame corresponds to one point on the helix representing angular sampling as the resin vial rotates and time progresses. As projections are recorded with a single fixed camera only one angular projection can be acquired at a time. For IndW and MW, dashed lines represent the timespan of the window. For IntW, they connect the referenced projections.

Kalender et al. introduced an approximate reconstruction technique for spiral projection acquisition geometry in which the hu-man patient moves continuously through the continuously-rotating x-ray scanner gantry. In this configuration, only one projection is acquired for any given slice orthogonal to the z-axis of the patient (which is also the axis of patient movement). Therefore, to estimate complete data for a virtual reconstruction z-slice, the missing projection data is estimated by a linear interpolation of adjacent scans acquired at the same angles weighted by the scans' distance from the virtual plane. In our final approach, we adopt a similar interpolation window (IntW) scheme but weighted instead by temporal distance because the imaging sequence is moving spirally through time instead of along the z-axis.

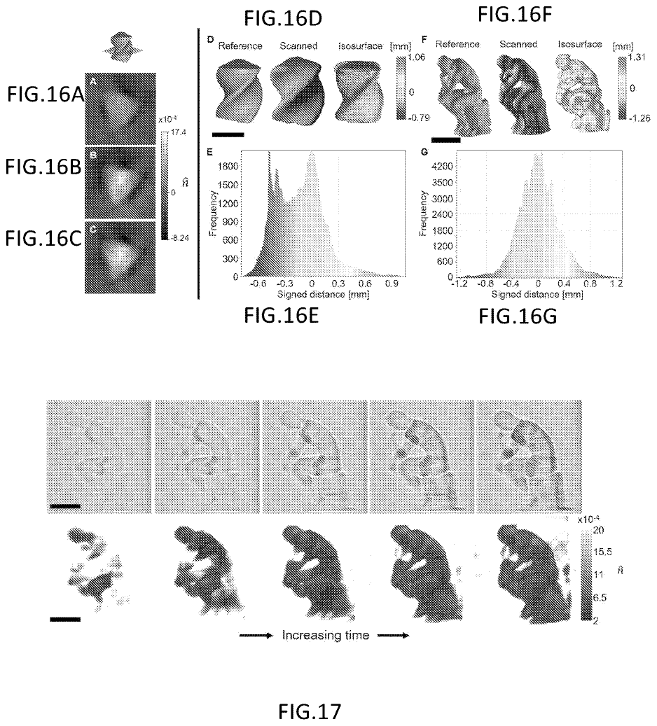

FIGS. 16A-16C show reconstructed n\hat{ }field slices using independent, moving and interpolation window time-segmentation methods, respectively, according to an embodiment of the present invention. FIG. 16A is reconstructed from 330-360 s (the 12th rotation), FIG. 16B is MW centered at 355 s (from 340-370 s) and FIG. 16C is IntW interpolated to 355 s. FIG. 16D shows a triangle helix “.stl” file compared to laser-scanned printed part and the isosurface of isovalue \hat{n}=4×10⁻⁴, according to an embodiment of the present invention. FIG. 16F shows a thinker “.stl” file compared to laser-scanned printed part and the isosurface of isovalue \hat{n}=2×10⁻⁴, according to an embodiment of the present invention. FIGS. 16E and 16G are histograms of signed distance of isosurface vertices in (FIG. 16D and FIG. 16F), respectively, from scanned meshes, according to an embodiment of the present invention. FIGS. 16D-16G are obtained with the IntW method, according to an embodiment of the present invention. Scale bars: 5 mm.

First, we select a virtual time plane, the instantaneous time at which the RI field is to be reconstructed (FIGS. 16A-16G). Then, projection deflection data is interpolated onto this virtual time plane by referencing projections less than one period, T, before or after:

$${ε}_{θ} ( t , z ) = ( 1 - σ ) {ε}_{θ} ( τ , z ) + {ε}_{θ} ( τ + T , z ) \qquad ( 26 )$$

where ε_{θ}(t, z) is the estimated virtual projection data at time t and angle θ, τ is the latest time (before t) at which a projection is acquired for angle θ, ε_{θ}(t, z), and ε_{θ}(τ+T,z) are the previous and next projections (in time) acquired at the desired angle θ. The weighting factor σ is calculated as σ=(t−τ)/T.

Print and Reconstruction Results: Three reconstructions (FIGS. 16A-16C) are created using an image sequence with 180 frames per vial rotation captured during a print of length 455 seconds and 12°s rotational velocity at a requested reconstruction time of 355 seconds. FIG. 16A is a reconstruction slice of the nearest rotation of the print (from 330-360 s) generated with the IndW approach. FIG. 16B is a slice generated with a MW with center frame at 355 seconds (from 340-370 s). FIG. 16C is a slice generated with an IntW centered at the same time (referencing frames from (325-385 s). The face and vertex structured stereolithography “.stl” file which is used as the starting point of the projection design algorithm is shown in FIG. 16D and FIG. 16F, alongside laser scans (Romer RA-7525 SI) of the printed parts and isosurfaces that were extracted from the IntW-reconstructed n\hat{ } field near the end of the printing processes. Each isosurface is obtained with the marching cubes algorithm of the Python scikit-image image processing library with an isovalue of \hat{n}=4×10⁻⁴(D) and \hat{n}=2×10⁻⁴(F). The source of roughness on the scanned part surfaces could potentially be discretization errors from faceting point clouds, while the voxel-scale roughness on the isosurface results from the marching cube algorithm. The histograms in FIG. 16E and FIG. 16G are created by measuring the orthogonal projection length of isosurface vertices to the nearest triangles of the scanned mesh using the cloud-to-mesh tool in CloudCompare. With current hardware (Nvidia GTX 1050Ti and Ryzen 1600 3.4 GHz) images are processed at 28 fps and reconstruction of a 600×600×560 voxel volume requires 6 s.

In FIG. 17, the time progression of a print of length 650 seconds and 24° s rotational velocity is depicted in captured video frames and reconstructions using the IntW method. In frames at later times, strong horizontal striations are observed. These are attributed to the self-focusing of light that occurs due to non-simultaneous resin gelation. The averaging filter is applied to reduce their effect in the reconstructions.

In the comparison of various time-segmentation techniques, there are significant differences in reconstruction quality. Reconstructions generated by IndW showed lower maximum n\hat{ } and lower reconstruction-to-background contrast. This outcome is driven by the fact that this naïve approach provides only reconstructions centered at the middle of each rotation. Thus, in general, there is a time difference between the arbitrary requested time point and the center frame of the nearest reconstruction (see FIG. 15 for an illustration of the discrepancy). In this example, the center frame of IndW reconstruction lags those from other two methods by 10 s (⅓ period). Because the RI gradient strengthens over time due to polymerization, the n\hat{ } magnitude is underestimated.

With the MW approach, the reconstruction can be adequately centered around the requested time (355 s) because the nearest frame, instead of the nearest rotation, is selected as the center. However, compared to reconstruction with the IntW method, the MW approach introduces an azimuthal bias to the reconstructed RI cross-sections, as seen from the slightly darker upper-left and brighter bottom-right regions in FIG. 16B. This bias is a consequence of the fact that projections are acquired at increasing times (and angles), while the RI gradient is simultaneously increasing during the printing process.

Of the three time-segmentation methods evaluated, IntW is believed to create the most accurate and uniform results because it references two-periods-worth of frames for each reconstruction and corrects for the temporal refractive index changes that occur. With this method, the reconstruction can be centered at any moment in time instead of the nearest frame.

A comparison between the scanned mesh and the RI reconstruction reveals that the reconstruction error is the smallest at the helical surface (<˜0.3 mm in magnitude) and greatest at the helical edge (<−0.3 mm), excluding localized noise at the top of model. The localized undershoot error on the edge might come from the 15-pixel-wide smoothing action applied. Optimization of the smoothing filter may improve the fidelity with which sharper edges can be reconstructed, while preserving the effectiveness of striation and noise removal.

FIG. 17 shows in the top row color Schlieren images captured during a CAL print of Rodin's ‘Thinker’ and in the bottom row corresponding reconstructed 3D n\hat{ } fields, according to an embodiment of the present invention. Columns correspond to frames and reconstructions 510, 540, 570, 600, and 630 seconds, respectively. Scale bars: 5 mm.

In FIG. 17, the fidelity of reconstruction can be qualitatively observed. At each time point, the topology of the n field closely resembles that suggested by the videoframes. FIGS. 16A-16B and FIG. 17 indicate the absolute maximum normalized RI changes are on the order of 10-4. For instance, the maximum n\hat{ } predicted for the final reconstruction in FIG. 17 is 20×10⁻⁴, which corresponds to n=1.4968 (Δn=0.003). Although this RI change is seemingly rather weak, it is of the same order of magnitude as the values reported for UDMA-IPDI resin upon polymerization. Quantitative verification of the result would require measurement of a standard target whose RI is both accurately known and close enough to that of the resin that all RI gradients remain within the measurement range when observed from any angle. For instance, the hue-calibration lens does not meet the latter criterion because at such RI, deflection is saturated when rays pass through a high transverse gradient along the planar side. This verification will also help to explain the negative index changes in FIGS. 16A-16G.

The existence of non-uniform background hue (as shown in FIG. 14C) is due to imperfect index matching and astigmatism correction. This background hue, although subtracted from projections, reduced the effective measurement range. Therefore, measurement saturation occurs earlier in regions where the background hue differs strongly from the center hue and prevented utilization of the full field of view.

The measured hue-deflection relationship is non-linear due to recording imperfections of the photographic filter and the unbalanced spectral distribution of the tungsten white light source. Al-though the deflection estimate remains accurate within the measurement range, the measurement sensitivity is shift-variant. We attempted to create filters that compensate for such non-linearity using the optimization method proposed by Greenberg et al. While linearity was improved over portions of the filter, we have not yet been able to achieve a linear deflection-hue relationship in the full 0-360° hue range.

In these experiments, vial rotational eccentricity was reduced as much as possible with the current fixturing. However, it was not eliminated and could have reduced the sharpness of reconstructions. Without perfect index matching, eccentricity or ‘wobble’ results in a periodic lateral shift of the source image on the filter which leads to the mentioned undesirable background hue and sensitivity changes dependent on azimuth angle. With improved fixturing, these challenges could be reduced. Furthermore, time-segmentation windows could be shortened to half of their current respective lengths by employing the 180° projection symmetry assumption (p_{θ}(t)=(p_{θ±π}(−t)), such that faster material transformation kinetics could be captured.

As it can be appreciated from the above paragraphs, the results of this work can support the development of a real-time feedback CAL system where the projection images could be corrected during printing to: (1) reduce manual iterative experimentation for materials with unknown contrast and gelation threshold, and (2) induce a uniform degree of cure for simultaneous gelation throughout the printed object, which would have significant implications for print fidelity. In addition, the printing process can be terminated automatically based on a specified or machine learned material-specific Δn, preventing overcuring and inaccurate part dimensions. Practically, real-time integration can be achieved with asynchronous image input/processing and reconstruction, all on faster computing hardware, within the time of a fraction of single rotation (currently ˜⅓T for fastest wo).

### REFERENCES

T. D. Ngo, A. Kashani, G. Imbalzano, K. T. Nguyen, D. Hui, Additive manufacturing (3D printing): A review of materials, methods, applications and challenges, Composites B 143 (February) (2018) 172-196, http://dx.doi.org/10.1016/j.compositesb.2018.02.012, URL https://linkinghub.elsevier.com/retrieve/pii/S1359836817342944.
J. Delgado, L. Serenó, K. Monroy, J. Ciurana, Selective laser sintering, in: M. Koç, T. Özel (Eds.), Modern Manufacturing Processes, John Wiley & Sons, Inc., Hoboken, N J, USA, 2019, pp. 481-499, http://dx.doi.org/10.1002/9781119120384.ch20, URL https://linkinghub.elsevier.com/retrieve/pii/C20190003147 http://doi.wiley.com/10.1002/9781119120384http://doi.wiley.com/10.1002/97811191203 84.ch20.
P. J. Bártolo (Ed.), Stereolithography, Springer U S, Boston, M A, 2011, http://dx.doi.org/10.1007/978-0-387-92904-0, URL http://link.springer.com/10.1007/978-0-387-92904-0.
E. Napadensky, Inkjet 3D printing, in: The Chemistry of Inkjet Inks, WORLD SCIENTIFIC, 2009, pp. 255-267, http://dx.doi.org/10.1142/9789812818225_0013, URL http://www.worldscientific.com/doi/abs/10.1142/9789812818225{_}0013.
J. R. Tumbleston, D. Shirvanyants, N. Ermoshkin, R. Janusziewicz, A. R. Johnson, D. Kelly, K. Chen, R. Pinschmidt, J. P. Rolland, A. Ermoshkin, E. T. Samulski, J. M. DeSimone, Continuous liquid interface production of 3D objects, Science 347 (6228) (2015) 1349-1352, http://dx.doi.org/10.1126/science.aaa2397.
E. Cuan-Urquizo, E. Barocio, V. Tejada-Ortigoza, R. Pipes, C. Rodriguez, A. Roman-Flores, Characterization of the mechanical properties of FFF structures and materials: A review on the experimental, computational and theoretical approaches, Materials 12 (6) (2019) 895, http://dx.doi.org/10.3390/mal 2060895, URL https://www.mdpi.com/1996-1944/12/6/895.
C. Dai, C. C. L. Wang, C. Wu, S. Lefebvre, G. Fang, Y.-J. Liu, Support-free volume printing by multi-axis motion, ACM Graph. Trans. 37 (4) (2018) 1-14, http://dx.doi.org/10.1145/3197517.3201342, URL https://dl.acm.org/doi/10.1145/3197517.3201342.
G. Fang, T. Zhang, S. Zhong, X. Chen, Z. Zhong, C. C. L. Wang, Reinforced FDM: Multi-axis filament alignment with controlled anisotropic strength, ACM Trans. Graph. 39 (6) (2020) 1-15, http://dx.doi.org/10.1145/3414685.3417834, URL https://dl.acm.org/doi/10.1145/3414685.3417834.
M. Shusteff, A. E. Browar, B. E. Kelly, J. Henriksson, T. H. Weisgraber, R. M. Panas, N. X. Fang, C. M. Spadaccini, One-step volumetric additive manufacturing of complex polymer structures, Sci. Adv. 3 (12) (2017) http://dx.doi.org/10.1126/sciadv.aao5496.
B. E. Kelly, I. Bhattacharya, H. Heidari, M. Shusteff, C. M. Spadaccini, H. K. Taylor, Volumetric additive manufacturing via tomographic reconstruction, Science 363 (6431) (2019) http://dx.doi.org/10.1126/science.aau7114, URL https://science.sciencemag.org/content/363/6431/1075.
D. Loterie, P. Delrot, C. Moser, High-resolution tomographic volumetric additive manufacturing Nature Commun. 11 (1) (2020) 852, http://dx.doi.org/10.1038/s41467-020-14630-4, URL http://www.nature.com/articles/s41467-020-14630-4.
C. C. Cook, E. J. Fong, J. J. Schwartz, D. H. Porcincula, A. C. Kaczmarek, J. S. Oakdale, B. D. Moran, K. M. Champley, C. M. Rackson, A. Muralidharan, R. R. McLeod, M. Shusteff, Highly tunable thiolne photoresins for volumetric additive manufacturing, Adv. Mater. 32 (47) (2020) 2003376, http://dx.doi.org/10.1002/adma.202003376, URL https://onlinelibrary.wiley.com/doi/10.1002/adma.202003376.
L. Moroni, T. Boland, J. A. Burdick, C. De Maria, B. Derby, G. Forgacs, J. Groll, Q. Li, J. Malda, V. A. Mironov, C. Mota, M. Nakamura, W. Shu, S. Takeuchi, T. B. Woodfield, T. Xu, J. J. Yoo, G. Vozzi, Biofabrication: A guide to technology and terminology, Trends Biotechnol. 36 (4) (2018) 384-402, http://dx.doi.org/10.1016/j.tibtech.2017.10.015.
S. Kim, D. H. Kim, W. Kim, Y. T. Cho, N. X. Fang, Additive manufacturing of functional microarchitected reactors for energy, environmental, and biological applications, Int. J. Precis. Eng. Manuf.-Green Technol. 8 (1) (2021) 303-326, http://dx.doi.org/10.1007/s40684-020-00277-5.
A. C. Kak, M. Slaney, Principles of Computerized Tomography, SIAM, 2001, (book).
P. N. Bernal, P. Delrot, D. Loterie, Y. Li, C. M. Jos Malda, R. Levato, Volumetric bioprinting of complex living-tissue constructs within seconds, Adv. Mater. 31 (190429) (2019) http://dx.doi.org/10.1186/s13014-018-1179-7.
O. Tretiak, C. Metz, The exponential radon transform, SIAM J. Appl. Math. 39 (2) (1980) 341-354, URL https://epubs.siam.org/doi/abs/10.1137/0139029.
R. H. Byrd, P. Lu, J. Nocedal, A limited memory algorithm for bound constrained optimization, SIAM J. Sci. Statist. Comput. 16 (5) (1995) 1190-1208.
C. Chung Li, J. Toombs, H. Taylor, Tomographic color schlieren refractive index mapping for computed axial lithography, in: Proceedings—SCF 2020: ACM Symposium on Computational Fabrication, 2020, http://dx.doi.org/10.1145/3424630.3425421.
H. K. Taylor, J. Toombs, S. M. Luk, S. Feili, H. Heidari, C. C. Li, V. Bansal, K. Coulson, E. Goli, Modeling of light propagation in computed axial lithography with photopolymers, in: B. L. Lee, J. Ehmke (Eds.), Emerging Digital Micromirror Device Based Systems and Applications XIII, SPIE, 2021, http://dx.doi.org/10.1117/12.2580631.
CloudCompare, URL http://www.cloudcompare.org/.
C. Decker, D. Decker, F. Morel, Light intensity and temperature effect in photoinitiated polymerization, ACS Symp. Ser. 673 (1997) 63-80, http://dx.doi.org/10.1021/bk-1997-0673.ch006.
M. D. Goodner, C. N. Bowman, Development of a comprehensive free radical photopolymerization model incorporating heat and mass transfer effects in thick films, Chem. Eng. Sci. 57 (5) (2002) 887-900, http://dx.doi.org/10.1016/S0009-2509(01)00287-1, URL https://linkinghub.elsevier.com/retrieve/pii/S0109564116300574 https://linkinghub.elsevier.com/retrieve/pii/S0009250901002871.
A. K. O'Brien, C. N. Bowman, Impact of oxygen on photopolymerization kinetics and polymer structure, Macromolecules 39 (7) (2006) 2501-2506, http://dx.doi.org/10.1021/ma0518631, URL https://pubs.acs.org/sharingguidelines https://pubs.acs.org/doi/10.1021/ma0518631.
D. Dendukuri, P. Panda, R. Haghgooie, J. M. Kim, T. A. Hatton, P. S. Doyle, Modeling of oxygen-inhibited free radical photopolymerization in a PDMS microfluidic device, Macromolecules 41 (22) (2008) 8547-8556, http://dx.doi.org/10.1021/ma801219w.
T. G. Hiss, E. Cussler, Diffusion in high viscosity liquids, AIChE J. 19 (4) (1973) 698-703, http://dx.doi.org/10.1002/aic.690190404.
P. Müller, M. Schürmann, J. Guck, The theory of diffraction tomography, 2016, arXiv. URL https://arxiv.org/abs/1507.00466.
F. Andersson, M. Carlsson, V. V. Nikitin, Fast Laplace transforms for the exponen-tial radon transform, J. Fourier Anal. Appl. 24 (2) (2017) 431-450, http://dx.doi.org/10.1002/adma.201904209, URL https://doi.org/10.1002/adma.201904209.
Wim van Aarle, Willem Jan Palenstijn, Jeroen Cant, Eline Janssens, Folkert Bleichrodt, Andrei Dabravolski, Jan De Beenhouwer, K Joost Batenburg, and Jan Sijbers. 2016. Fast and flexible X-ray tomography using the ASTRA toolbox. Optics Express 24, 22:25129. https://doi.org/10.1364/OE.24.025129
Ajay K. Agrawal, Nelson K. Butuk, Subramanyam R. Gollahalli, and De Von Griffin. 1998. Three-dimensional rainbow schlieren tomography of a temperature field in gas flows. Applied Optics 37, 3:479. https://doi.org/10.1364/ao.37.000479
Lingling Chen, Sunil Kumar, Douglas Kelly, Natalie Andrews, Margaret J Dallman, Paul
M. W. French, and James McGinty. 2014. Remote focal scanning optical projection tomography with an electrically tunable lens. Biomedical Optics Express 5, 10:3367. https://doi.org/10.1364/BOE.5.003367
S. Décamp, C. Kozack, and B. R. Sutherland. 2008. Three-dimensional schlieren measurements using inverse tomography. Experiments in Fluids 44, 5: 747-758. https://doi.org/10.1007/s00348-007-0431-y
Ah-Hyang Eom, Duck-Su Kim, Soo-Hee Lee, Chang-Won Byun, Noh-Hoon Park, and Kyoung-Kyu Choi. 2011. Optical characteristics of resin composite before and after polymerization. Journal of Korean Academy of Conservative Dentistry 36, 3:219. https://doi.org/10.5395/jkacd.2011.36.3.219
Gregory W Faris and Robert L Byer. 1988. Three-dimensional beam-deflection optical tomography of a supersonic jet. Applied Optics 27, 24:5202. https://doi.org/10.1364/AO.27.005202
Daniel Girardeau-Montaut. 2020. CloudCompare (version 2.6) [GPL software]. Retrieved from http://www.cloudcompare.org/
Rafael C. Gonzalez, Richard E. Woods, and Barry R. Masters. 2009. Digital Image Processing Third Edition. https://doi.org/10.1117/1.3115362
Paul S. Greenberg, Robert B. Klimek, and Donald R. Buchele. 1995. Quantitative rainbow schlieren deflectometry. Applied Optics 34, 19:3810. https://doi.org/10.1364/ao.34. 003810
Avinash C. Kak, Malcolm Slaney, and Ge Wang. 2002. Principles of Computerized Tomographic Imaging. Medical Physics 29, 1:107-107. https://doi.org/10.1118/1.1455742
W A Kalender, W Seissler, E Klotz, and P Vock. 1990. Spiral volumetric C T with single-breath-hold technique, continuous transport, and continuous scanner rotation. Radiology 176, 1: 181-183. https://doi.org/10.1148/radiology.176.1.2353088
Brett E. Kelly, Indrasen Bhattacharya, Hossein Heidari, Maxim Shusteff, Christopher M. Spadaccini, and Hayden K. Taylor. 2019. Volumetric additive manufacturing via tomographic reconstruction. Science 363, 6431:1075-1079. https://doi.org/10.1126/science.aau7114
Thomas Lewiner, Hélio Lopes, Antonio Wilson Vieira, and Geovan Tavares. 2003. Efficient Implementation of Marching Cubes' Cases with Topological Guarantees. Journal of Graphics Tools 8, 2: 1-15. https://doi.org/10.1080/10867651.2003.10487582
Damien Loterie, Paul Delrot, and Christophe Moser. 2020. High-resolution tomographic volumetric additive manufacturing. Nature Communications 11, 1:852. https://doi. org/10.1038/s41467-020-14630-4
Carolyn R. Mercer (ed.). 2003. Optical Metrology for Fluids, Combustion and Solids. Springer U S, Boston, M A. https://doi.org/10.1007/978-1-4757-3777-6
W. J. Palenstijn, K. J. Batenburg, and J. Sijbers. 2011. Performance improvements for iterative electron tomography reconstruction using graphics processing units (GPUs). Journal of Structural Biology 176, 2:250-253. https://doi.org/10.1016/j.jsb.2011.07.017
Markus Raffel. 2015. Background-oriented schlieren (BOS) techniques. Experiments in Fluids 56, 3:60. https://doi.org/10.1007/s00348-015-1927-5
W. Schlegel, T. Bortfeld, and A.-L. Grosu. 2006. New Technologies in Radiation Oncology. Springer Berlin Heidelberg, Berlin, Heidelberg.
Gary S. Settles. 2001. Schlieren and Shadowgraph Techniques. Springer Berlin Heidelberg Berlin, Heidelberg. https://doi.org/10.1007/978-3-642-56640-0
Gary S. Settles and Michael J. Hargather. 2017. A review of recent developments in schlieren and shadowgraph techniques. Measurement Science and Technology 28, 4. https://doi.org/10.1088/1361-6501/aa5748
James Sharpe. 2004. Optical Projection Tomography. Annual Review of Biomedical Engineering 6, 1:209-228. https://doi.org/10.1146/annurev.bioeng.6.040803.140210
Chris C. Shaw. 2014. Cone Beam Computed Tomography. Taylor & Francis, Boca Raton, Florida. https://doi.org/10.1016/B978-1-4377-0867-7.00070-3
Atul Srivastava. 2013. Development and application of color schlieren technique for investigation of three-dimensional concentration field. Journal of Crystal Growth 383:131-139. https://doi.org/10.1016/j.jcrysgro.2013.09.001
A. Töpler. 1867. Optische Studien nach der Methode der Schlierenbeobachtung. Annalen der Physik und Chemie 207, 6:180-215. https://doi.org/10.1002/andp. 18672070603
Stéfan Van Der Walt, Johannes L. Schönberger, Juan Nunez-Iglesias, François Boulogne, Joshua D. Warner, Neil Yager, Emmanuelle Gouillart, and Tony Yu. 2014. Scikit-image: Image processing in python. PeerJ 2014, 1:1-18. https://doi.org/10.7717/peerj.453
Thomas Watson. 2017. Advances In optical projection tomography. Imperial College London. Retrieved from All Papers/W/Watson-Advances In optical projection tomography.pdf

The embodiments illustrated and discussed in this specification are intended only to teach those skilled in the art how to make and use the invention. In describing embodiments of the disclosure, specific terminology is employed for the sake of clarity. However, the disclosure is not intended to be limited to the specific terminology so selected. The above-described embodiments, and following examples, may be modified or varied, without departing from the invention, as appreciated by those skilled in the art in light of the above teachings. It is therefore to be understood that, within the scope of the claims and their equivalents, the invention may be practiced otherwise than as specifically described. For example, it is to be understood that the present disclosure contemplates that, to the extent possible, one or more features of any embodiment can be combined with one or more features of any other embodiment.

1. A method of producing a three-dimensional object, comprising:
providing a volume of radiation-reactive material;
illuminating said radiation-reactive material with patterned radiation such that a portion of said volume of radiation-reactive material corresponding to said three-dimensional object reacts to form said three-dimensional object and a remaining portion remains unreacted; and
removing said remaining portion of said radiation-reactive material to provide said three-dimensional object,
wherein said illuminating said radiation-reactive material with patterned radiation is based on a minimization of deviations of an energy deposition density below a first threshold in an object zone, an unconstrained buffer zone surrounding said object zone, and a minimization of deviations of energy deposition density above a second threshold in a zone surrounding said buffer zone, and
wherein said object zone corresponds to a location of said three-dimensional object.

2. The method of claim 1, wherein a loss function is defined as a function of said deviations of said energy deposition density below said first threshold, and of said deviations of energy deposition density above said second threshold, and
wherein said loss function is minimized to determine said illuminating to be performed.

3. The method of claim 2, wherein said loss function is a continuous differentiable function.

4. The method of claim 3, wherein said loss function is
$${ℒ}_{PM} [ t ] := {ρ}_{1} {\int }_{\sim {V}_{2} [ t ]} ( f ( r ) - {d}_{l} ) d r + {ρ}_{2} {\int }_{\sim {V}_{1} [ t ]} ( {d}_{h} - f ( r ) ) d r .$$
as defined in the specification.

5. The method of claim 1, wherein said radiation-reactive material is a photoactive material, and wherein said illuminating said radiation-reactive material with patterned radiation is an optical computed axial lithographic illuminating.

6. A system for producing a three-dimensional object, comprising:
a target volume structured to contain radiation-reactive material; and
an illumination system configured to be arranged proximate said target volume,
wherein said illumination system is configured to provide patterned radiation such that a portion of said volume of radiation-reactive material corresponding to said three-dimensional object reacts to form said three-dimensional object and a remaining portion remains unreacted; and
wherein said illumination system is further configured to provide said patterned radiation based on a minimization of deviations of an energy deposition density below a first threshold in an object zone, an unconstrained buffer zone surrounding said object zone, and a minimization of deviations of energy deposition density above a second threshold in a zone surrounding said buffer zone, and
wherein said object zone corresponds to a location of said three-dimensional object.

7. The system of claim 6, wherein a loss function is defined as a function of said deviations of said energy deposition density below said first threshold, and of said deviations of energy deposition density above said second threshold, and
wherein said loss function is minimized to determine said illuminating to be performed.

8. The system of claim 7, wherein said loss function is a continuous differentiable function.

9. The system of claim 8, wherein said loss function is
$${ℒ}_{PM} [ t ] := {ρ}_{1} {\int }_{\sim {V}_{2} [ t ]} ( f ( r ) - {d}_{l} ) d r + {ρ}_{2} {\int }_{\sim {V}_{1} [ t ]} ( {d}_{h} - f ( r ) ) d r .$$
as defined in the specification.

10. The system of claim 6, wherein said radiation-reactive material is a photoactive material, and wherein said illumination system is an optical computed axial lithographic illumination system.

11. A method of producing a three-dimensional object, comprising:
providing a volume of photoreactive material;
illuminating said photoreactive material with patterned light such that a portion of said volume of photoreactive material corresponding to said three-dimensional object reacts to form said three-dimensional object and a remaining portion remains unreacted;
measuring changes in refractive index of said photoreactive material during said illuminating using color schlieren tomographic imaging;
determining exposure errors in said volume of photoreactive material during said illuminating and modifying said illuminating to correct at least some of said exposure errors; and
removing said remaining portion of said photoreactive material to provide said three-dimensional object.

12. A system for producing a three-dimensional object, comprising:
a target volume structured to contain photoactive material;
an optical computed axial lithographic illumination system arranged proximate said target volume structured; and
a color schlieren tomographic imaging system arranged proximate said target volume structured,
wherein said color schlieren tomographic imaging system is configured to communicate with said optical computed axial lithographic illumination system to provide feedback control thereof.
